(19) United States
(12) Patent Application Publication
(10) Pub. No.: US 2013/0170192 A1
(43) Pub. Date: Jul. 4, 2013

(54) DYE-LABELED POLYMER, SOLAR COLLECTOR AND METHODS FOR MANUFACTURING THE SAME, AND SOLAR CELL MODULE, AND OFF-GRID LAMP USING THE COLLECTOR

(71) Applicant: INDUSTRIAL TECHNOLOGY RESEARCH INSTITUTE, Hsinchu (TW)

(72) Inventors: Ming-Hsien WU, Tainan County (TW); Ming-Chia LI, Taichung County (TW); Wen-Yih LIAO, Taichung City (TW)

(73) Assignee: INDUSTRIAL TECHNOLOGY RESEARCH INSTITUTE, Hsinchu (TW)

(21) Appl. No.: 13/730,344

(22) Filed: Dec. 28, 2012

(30) Foreign Application Priority Data
Dec. 30, 2011 (TW) 100149771
Dec. 30, 2011 (TW) 100149776
Dec. 27, 2012 (CN) 201210579910.0

(51) Int. Cl. H01L 31/055; F21L 4/08; H01L 31/18

(52) U.S. Cl. CPC H01L 31/055; H01L 31/18; F21L 4/08
USPC 362/183; 136/247; 528/354; 29/428; 29/530

(57) ABSTRACT

A dye-labeled polymer includes a fluorescent dye moiety and a polymer moiety, wherein the fluorescent dye moiety and the polymer moiety are connected through a chemical bond.

A luminescent solar collector is provided. The luminescent solar collector includes: a waveguide; a wavelength conversion material disposed on the waveguide, wherein the wavelength conversion material includes 0-95 parts by weight of a polymer material; and 5-100 parts by weight of the previously described dye-labeled polymer, wherein the polymer material is different from the dye-labeled polymer.

A fluorescent column embedded solar collector includes: a waveguide; and at least one fluorescent column embedded in the waveguide, wherein the fluorescent column contains a wavelength conversion material.

### CROSS REFERENCE TO RELATED APPLICATIONS

This application claims priority of Taiwan Patent Application No. 100149776, filed on Dec. 30, 2011; priority of Taiwan Patent Application No. 100149771, filed on Dec. 30, 2011, and priority of China Patent Application No. ______, filed on Dec. 27, 2012, the entirety of which is incorporated by reference herein.

### TECHNICAL FIELD

The technical field relates to a dye-labeled polymer, a solar collector and methods for manufacturing the same, and a solar cell module, and an off-grid lamp using the collector.

### BACKGROUND

Recently, environmental protection has become an important issue, and research related to the environment, such as in the solar cell industry, has also become more and more popular. In the solar cell industry, about 90% of the commercial solar cells are silicon-based solar cells. However, although the photoelectric conversion rate of a silicon-based solar cell is stable, the average photoelectric conversion rate is still less than 20%.

On the other hand, the photoelectric conversion rate of a compound semiconductor solar cell is higher than the photoelectric conversion rate of the silicon-based solar cell. However, the materials and processing cost of a compound semiconductor solar cell are higher than a silicon-based solar cell. Therefore, it is difficult for a compound semiconductor solar cell to be used in everyday life.

An advantage of a thin film solar cell is that its cost is low. However, its photoelectric conversion rate and reliability are low. Therefore, its development is limited.

Main difficulties in commercializing the compound semiconductor solar cell are its high cost and low photoelectric conversion rate. In addition, the size of a solar cell system is too large to be used in a light and portable product.

### SUMMARY

An embodiment of the disclosure provides a dye-labeled polymer, including a fluorescent dye moiety and a polymer moiety, wherein the fluorescent dye moiety and the polymer moiety are connected by a chemical bond.

Another embodiment of the disclosure provides a solar collector, including: a waveguide; a wavelength conversion material disposed on the waveguide, wherein the wavelength conversion material includes: 0-95 parts by weight of a polymer material; and 5-100 parts by weight of the dye-labeled polymer described previously, wherein the polymer material is different from the dye-labeled polymer.

Another embodiment of the disclosure provides a solar collector, including: a waveguide; at least one fluorescent column embedded in the waveguide, wherein the fluorescent column includes a wavelength conversion material, and the wavelength conversion material absorbs light having a first wavelength and emits light having a second wavelength, wherein the first wavelength is smaller than the second wavelength.

Another embodiment of the disclosure provides a method for manufacturing a solar collector, including: providing a first waveguide and a second waveguide; forming at least one first cylinder trench at a surface of the first waveguide; filling a first fluorescent material into the first cylinder trench to form a first fluorescent column; and assembling the first waveguide and the second waveguide, wherein the first fluorescent column is embedded between the first waveguide and the second waveguide to form an embedded fluorescent column.

Another embodiment of the disclosure provides a method for manufacturing a solar collector, including: providing a waveguide, wherein the waveguide has a main surface and a side surface; forming at least one cylinder hole from the side surface of the waveguide, wherein the cylinder hole extends into the waveguide; and filling a fluorescent material into the cylinder hole to embed a fluorescent column in the waveguide.

Another embodiment of the disclosure provides a method for manufacturing a solar collector, including: providing a first waveguide, wherein the first waveguide has at least one cylinder trench; coating a fluorescent material on the first waveguide; and attaching a second waveguide on the first waveguide having the fluorescent material, wherein the fluorescent material forms at least one fluorescent column in the cylinder trench.

Another embodiment of the disclosure provides a solar cell module, including: the solar collector described previously; and a solar cell optically coupled to the solar collector, collecting and converting light, which passes through the solar collector, into energy.

Another embodiment of the disclosure provides an off-grid lamp, comprising: the solar collector described previously; a solar cell optically coupled to the solar collector, collecting and converting light, which passes through the solar collector, into energy; an electricity storage device electrically connected to the solar cell, receiving and storing the electricity output from the solar cell; and a light emitting diode die electrically connected to the electricity storage device.

A detailed description is given in the following embodiments with reference to the accompanying drawings.

### BRIEF DESCRIPTION OF THE DRAWINGS

The present disclosure can be more fully understood by reading the subsequent detailed description and examples with references made to the accompanying drawings, wherein:

FIG. 1 illustrates a cross section of a solar collector containing the dye-labeled polymer according to one embodiment.

FIGS. 2a-4b illustrate waveguides having different structures according to various embodiments.

FIG. 5 illustrates a perspective view of a fluorescent column embedded solar collector according to one embodiment.

FIGS. 6a-6b illustrate cross section of conventional solar collectors.

FIG. 7 illustrates a cross section of a fluorescent column embedded solar collector according to one embodiment.

FIGS. 8a-9 illustrate cross section of fluorescent column embedded solar collectors according to various embodiments.

FIGS. 10a-11c illustrate perspective view of possible structures of fluorescent column embedded solar collectors according to various embodiments.

FIGS. 12 and 13 illustrate a manufacturing flowchart of a fluorescent column embedded solar collector and cross section of the fluorescent column embedded solar collector at various manufacturing stages according to one embodiment.

FIGS. 14 and 15 illustrate a manufacturing flowchart of a fluorescent column embedded solar collector and cross section of the fluorescent column embedded solar collector at various manufacturing stages according to another embodiment.

FIGS. 16 and 17 illustrate a manufacturing flowchart of a fluorescent column embedded solar collector and cross section of the fluorescent column embedded solar collector at various manufacturing stages according to still another embodiment.

FIGS. 18 and 19 illustrate a manufacturing flowchart of a fluorescent column embedded solar collector and cross section of the fluorescent column embedded solar collector at various manufacturing stages according to still another embodiment.

FIG. 20 illustrates a solar cell module according to one embodiment.

FIG. 21 illustrates a solar cell module according to another embodiment.

FIGS. 22a-22d illustrates solar cell modules using solar collector at FIG. 7 according to one embodiment.

FIG. 23 illustrates a block diagram of an off-grid lamp 2300? according to one embodiment.

FIGS. 24-26 illustrate off-grid lamps according to various embodiments.

FIG. 27 illustrates the transmittance of the solar collectors in one example and a comparative example.

FIG. 28 shows fluorescent intensities of the dye-labeled polymers of various examples.

### DETAILED DESCRIPTION OF DISCLOSED EMBODIMENTS

This following description is made for the purpose of illustrating the general principles of the disclosure and should not be taken in a limiting sense. The scope of the disclosure is best determined by reference to the appended claims.

Moreover, the formation of a first feature over and on a second feature in the description that follows may include embodiments in which the first and second features are formed in direct contact, and may also include embodiments in which additional features may be formed between the first and second features, wherein the first and second features may not be in direct contact.

Nowadays, difficulties in commercializing compound semiconductor solar cells are due to high costs and low photoelectric conversion rates. In some embodiments of the disclosure, a dye-labeled polymer is provided. The dye-labeled polymer may be used in a solar collector of a solar cell, wherein the solar collector may have better light collecting efficiency. In some other embodiments, a solar collector having an embedded fluorescent column is provided; wherein the fluorescent column embedded solar collector may also have better light collecting efficiency. In addition, in still another embodiment, the solar collector having an embedded fluorescent column may further comprise the dye-labeled polymer.

In one embodiment of the disclosure, a dye-labeled polymer is provided. The dye-labeled polymer may be used in a wavelength conversion material in a solar collector.

Conventionally, a wavelength conversion material is formed by mixing a fluorescent material and a polymer. However, resulting from the poor compatibility between the fluorescent material and the polymer, the fluorescent material and the polymer will form macrophase separation therebetween. Therefore, when this wavelength conversion material is used in a solar collector, the separation may cause light scattering, resulting in problems such as low transmittance, self-aggregation of the fluorescent material, decreased quantum efficiency, or the like.

Therefore, in one embodiment, a dye-labeled polymer is provided. The dye-labeled polymer comprises a fluorescent dye moiety and a polymer moiety, wherein the fluorescent dye moiety and the polymer moiety are connected by a chemical bond. By bonding a fluorescent dye moiety on a polymer (which has a better compatibility with the polymer material used in a wavelength conversion material), problems resulting from the poor compatibility between the fluorescent material and the polymer can be prevented.

Examples for the polymer moiety of the dye-labeled polymer may include, but are not limited to, moieties of poly(ε-caprolactone), polyethylene, polyvinyl alcohol, polystyrene, or copolymers thereof. It is noted that the polymers are merely examples and have been simplified for illustration, but the scope of the disclosure is not intended to be limiting. Examples for the fluorescent dye moiety may include, but are not limited to, 1,2-coumarin moiety, perylene moiety, naphthalene moiety, pyrene moiety, polymethine moiety, carbazole moiety, anthracene moiety, or combinations thereof.

A mole ratio of the polymer moiety to the fluorescent dye moiety is between 1:20 and 1:1000. When the dye-labeled polymer contains too much fluorescent dye moiety, the resulting dye-labeled polymer may tend to crystallize, resulting in a decrease of the transmittance. When the dye-labeled polymer contains too little fluorescent dye moiety, the resulting dye-labeled polymer may have a low photoelectric conversion rate. However, the mole ratio of the polymer moiety to the fluorescent dye moiety may be changed according to the polymer moiety used in the dye-labeled polymer. In other words, different fluorescent dye moieties and different polymer moieties may have their own preferable mole ratio. Therefore, one skilled in the art should understand that the mole ratio of the polymer moiety to the fluorescent dye moiety may be adjusted according to their applications, and the scope of the disclosure is not intended to be limiting.

Table 1 illustrates some examples of the dye-labeled polymers in various embodiments. The structures are, of course, merely examples and are not intended to be limiting.

TABLE 1

| | Dye-labeled polymers |
|---|---|
| 1 | 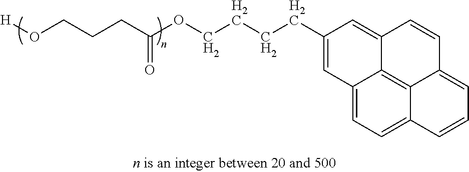 |
| 2 | 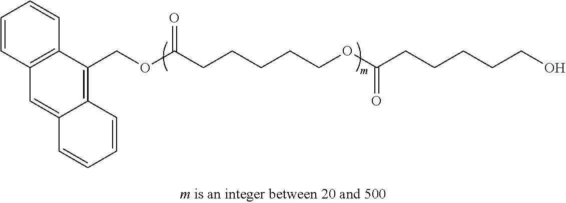 |
| 3 | 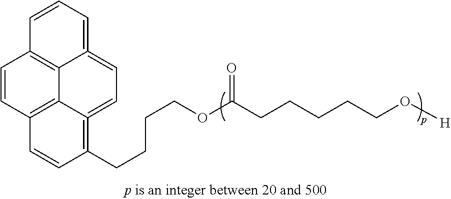 |
| 4 | 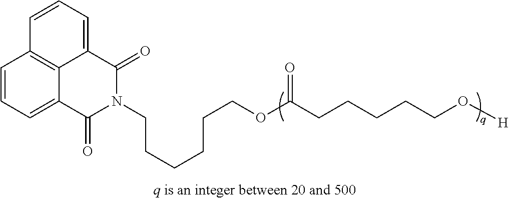 |
| 5 | 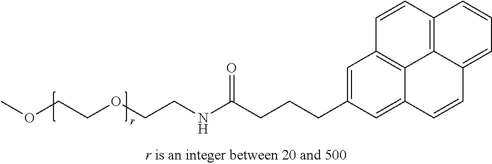 |
| 6 | 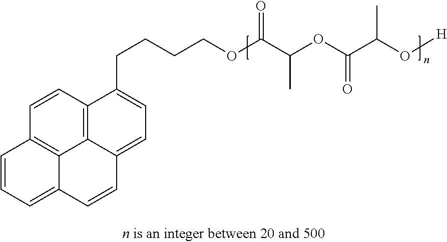 |
| 7 | 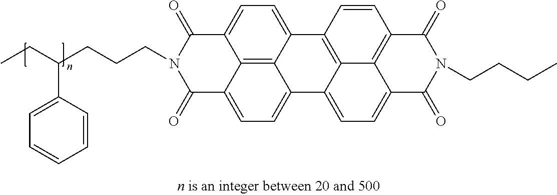 |
| 8 | 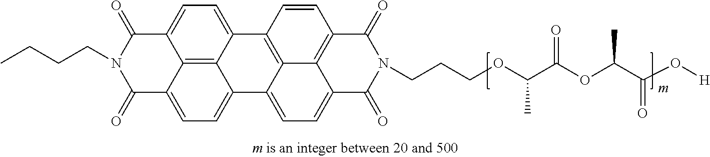 |
| 9 | 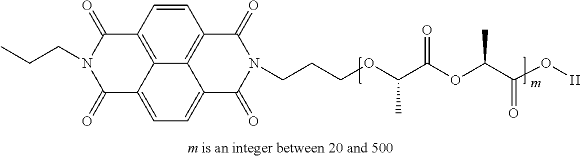 |
| 10 | 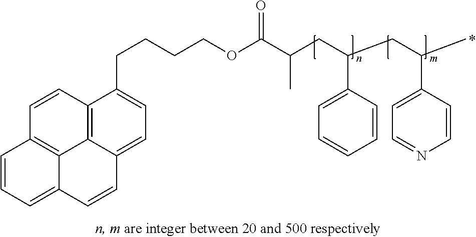 |

The dye-labeled polymers containing different fluorescent dye moiety and different polymer moiety may have different absorption wavelengths and photo luminescence wavelengths. According to one embodiment, the absorption wavelength of a dye-labeled polymer may be less than 400 nm, for example, between 200 nm and 400 nm. The photo luminescence wavelength of a dye-labeled polymer may be between 350 nm and 1100 nm. However, it is noted that the absorption wavelength and photo luminescence wavelength may be adjusted according to application requirements.

According to one embodiment, the dye-labeled polymer may be added into a polymer material to be used in a fluorescent solar collector. According to one embodiment, the solubility parameter of the dye-labeled polymer may be close to the solubility parameter of the polymer material. For example, the solubility parameter of the dye-labeled polymer may be between 8 MPa^{1/2} and 25 MPa^{1/2}. In addition, the solubility parameter of the dye-labeled polymer may be adjusted according to application requirements. For example, the solubility parameter of the dye-labeled polymer may be adjusted according to the polymer material, wherein the dye-labeled polymer may have better compatibility with the polymer material.

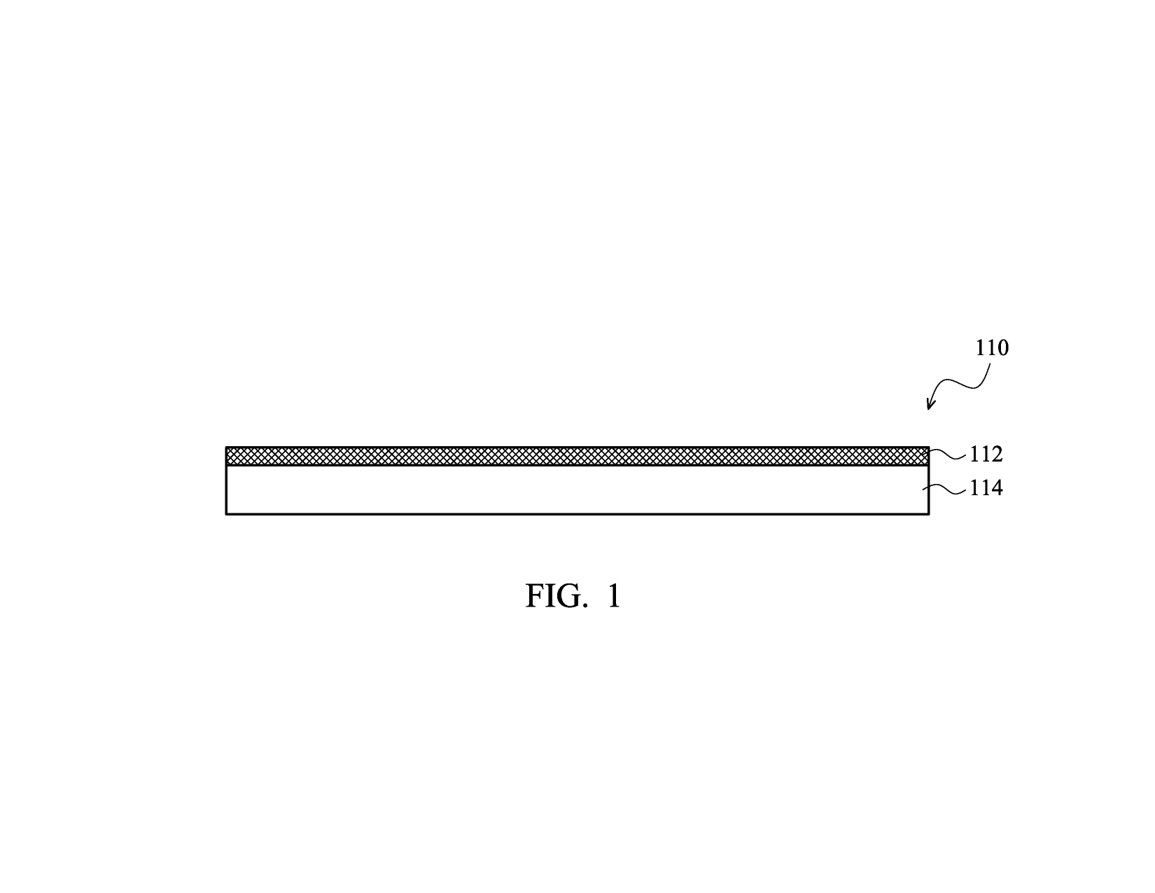

FIG. 1 illustrates a cross section of a solar collector 110 containing the dye-labeled polymer. The solar collector 110 comprises a waveguide 114 and a wavelength conversion material 112 coated on the waveguide 114. The wavelength conversion material 112 comprises 0-95 parts by weight of a polymer material, and 5-100 parts by weight of the dye-labeled polymer, wherein the polymer material is different from the dye-labeled polymer. Examples of the polymer material include, but are not limited to, polyethylene vinyl acetate, polymethacrylate, polycarbonate resin, poly vinyl butral, epoxy resin, or combinations thereof. In addition, the wavelength conversion material 112 may comprise one or various dye-labeled polymers, wherein the solar collector may have one or various colors. According to one embodiment, the wavelength conversion material may comprise 90 parts by weight of the polymer material and 10 parts by weight of the dye-labeled polymer.

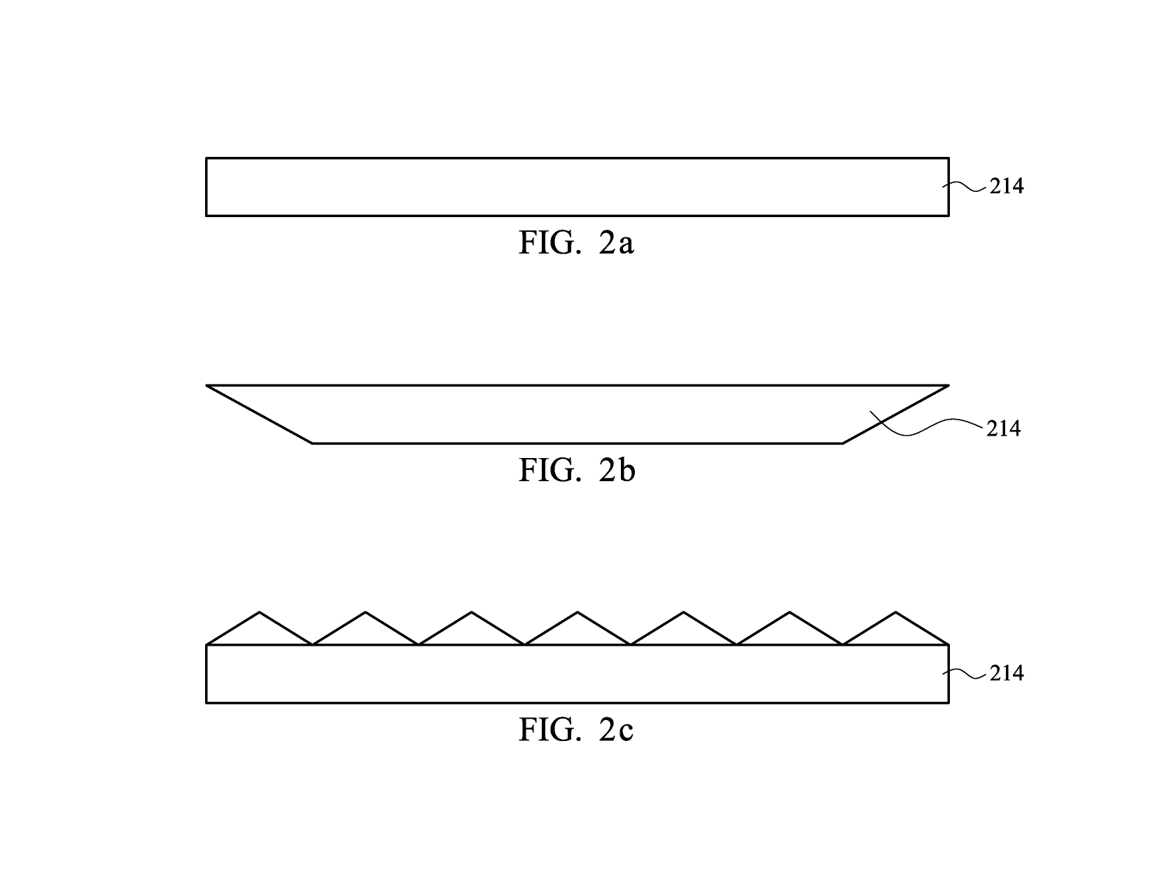

FIGS. 2a to 2c illustrates various possible structures of the waveguide 114 in various embodiments, comprising a conventional plane plate (as shown in FIG. 2a), wedge shape plate (as shown in FIG. 2b), or plate with micro-structures on its surface (as shown in FIG. 2c). According to one embodiment, the waveguide may be a rigid substrate, such as a glass or acrylic substrate. According to another embodiment, the waveguide may be a flexible substrate, such as a poly(ethylene vinyl acetate substrate, which can be rolled up for storage.

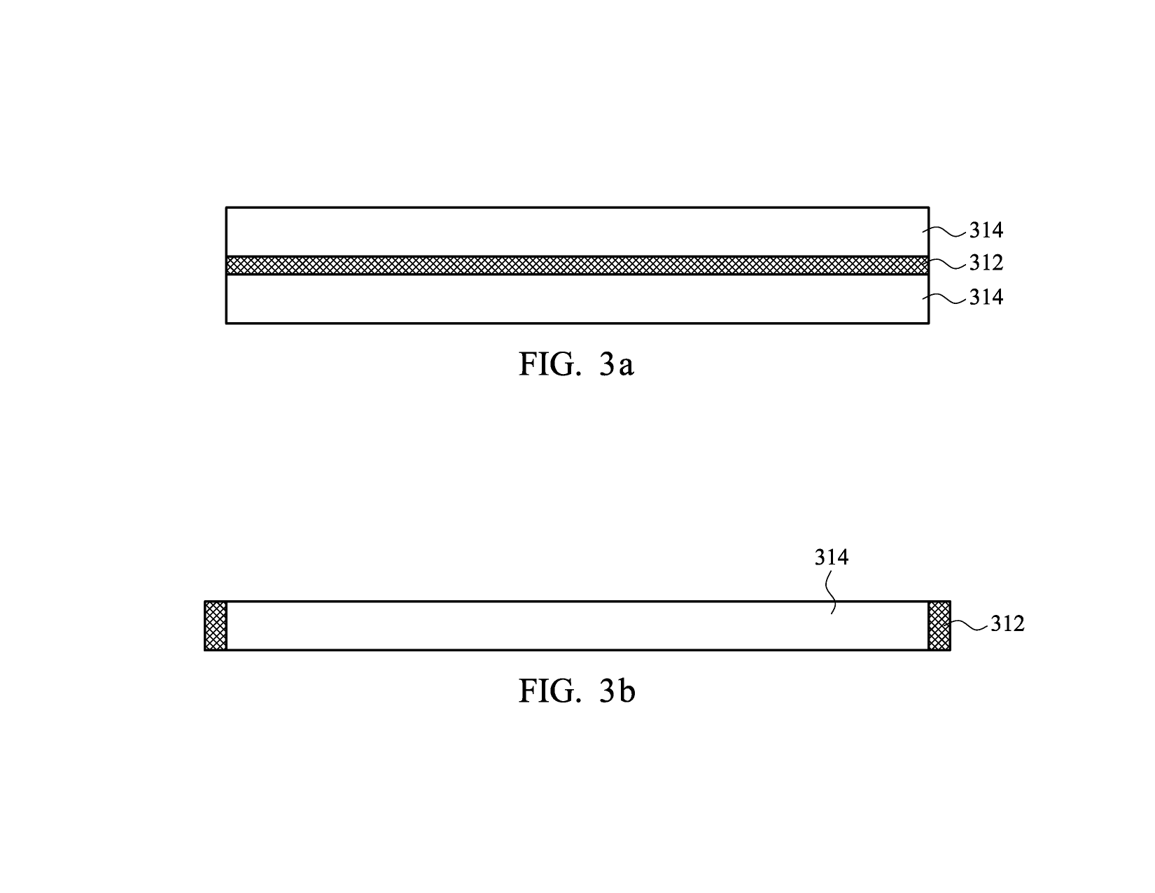

According to various embodiments, the waveguide and the wavelength conversion material may be assembled in different ways. For example, the wavelength conversion material 312 may be disposed between two waveguide 312, as shown in FIG. 3a. In another example, the wavelength conversion material 312 may be disposed at two sides of the waveguide 312, as shown in FIG. 3b.

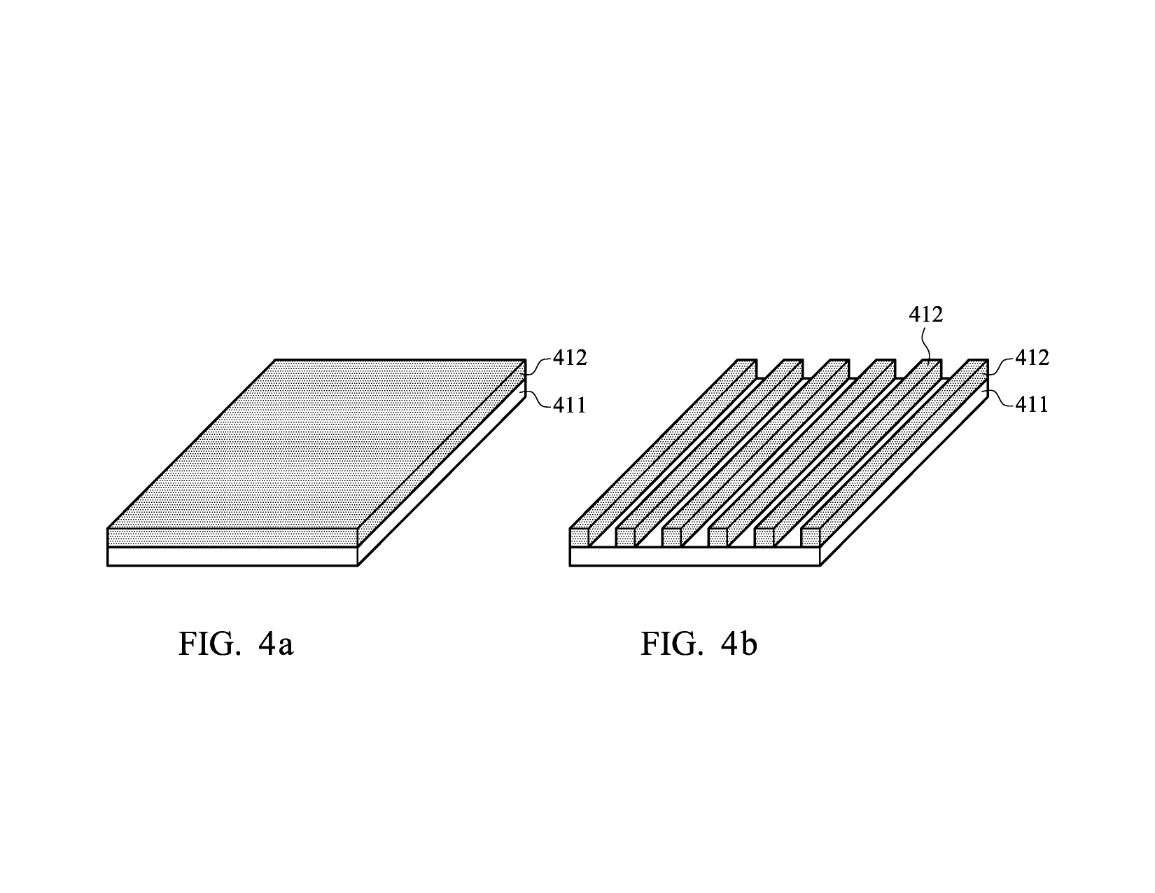

FIGS. 4a-4b illustrate a top view of the waveguides according to various embodiments. FIG. 4a illustrates the wavelength conversion material 412 coated onto the waveguide 411 evenly according to one embodiment. FIG. 4b illustrates the wavelength conversion material 412 disposed onto the waveguide 411, wherein the wavelength conversion material 412 may have a periodical pattern according to another embodiment. It is noted that the wavelength conversion material may be disposed onto the waveguide in different ways, for example, with an aperiodical pattern, according to some other embodiments.

In one embodiment, the solubility parameter of the dye-labeled polymer and solubility parameter of the polymer material are similar (close) to each other. Therefore, when the dye-labeled polymer is mixed with the polymer material, the difference of the solubility parameter between the dye-labeled polymer and the polymer material will not be as large as the conventional one is, and the problems resulting from the difference may be avoided. For example, poly(ethylene vinyl acetate), a conventionally used polymer material, has a solubility parameter of between about 16 MPa^{1/2} and 19 MPa^{1/2}. However, the solubility parameter of a conventional fluorescent material is between about 5.1 MPa^{1/2} and 7.5 MPa^{1/2}. In this case, the difference of the solubility parameter between the conventional fluorescent material and the polymer material is so large that self-aggregation of the fluorescent material may occur and the fluorescent quantum efficiency may decrease.

On the other hand, the solubility parameter of the dye-labeled polymer may be adjusted by choosing different fluorescent dye moieties and different polymer moieties according to various embodiments. Therefore, the solubility parameter of the polymer material can be matched by choosing the dye-labeled polymer with an appropriate solubility parameter. For example, a difference between a solubility parameter of the polymer material and a solubility parameter of the dye-labeled polymer may be between ±5 MPa^{1/2}. Therefore, the compatibility between the dye-labeled polymer and the polymer material is improved, and therefore the resulting solar collector may also have improved light collecting efficiency.

In addition, the improved compatibility may also result in an increase of the transparency. Furthermore, scattering light can also be used by the dye-labeled polymer. Therefore, the dye-labeled polymer may be used on glass used in buildings, such as a solar photovoltaic glass. It is noted that the dye-labeled polymer may not only be used in solar collectors but also be used in other devices. For example, the dye-labeled polymer may be coated onto the glass used in a building in a form of a film and its light collecting ability can still remain.

According to another embodiment of the disclosure, a fluorescent column embedded solar collector is provided. By using the pattern formed by the fluorescent column in a waveguide, better light collecting efficiency may be achieved. In the present embodiment, the fluorescent column may have a periodic pattern or have other specific patterns.

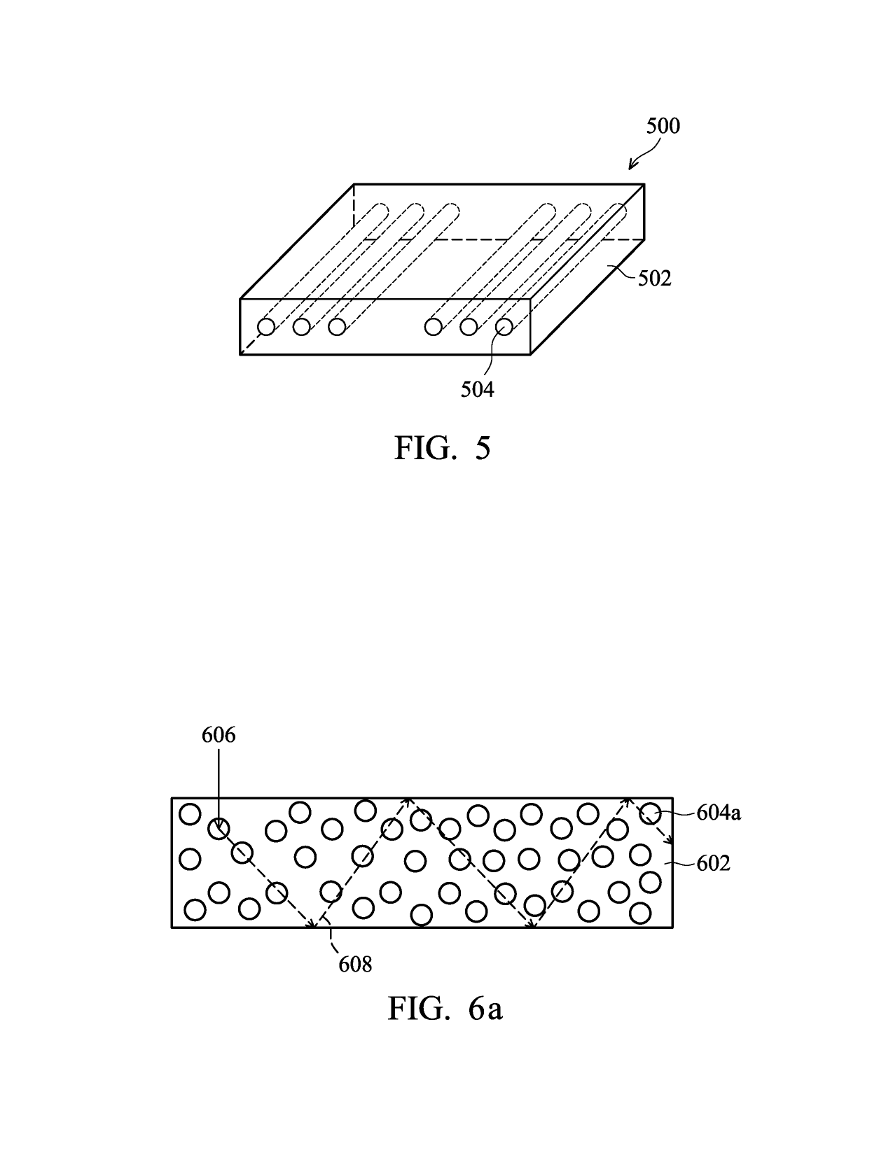

FIG. 5 illustrates a perspective view of a fluorescent column embedded solar collector according to one embodiment. The solar collector 500 comprises a waveguide 502 and a fluorescent column 504 embedded in the waveguide 502. The fluorescent column 504 comprises a wavelength conversion material, wherein the wavelength conversion material absorbs light having a first wavelength and emits light having a second wavelength, and the first wavelength is smaller than the second wavelength. According to one embodiment, the first wavelength is between 300 nm and 1000 nm, and the second wavelength is between 700 nm and 1000 nm. When incident light passes through the wavelength conversion material in the fluorescent column, the excited light will be isotropic (i.e. the excited light will be directed to all directions) and will be at total reflection in the waveguide. Therefore, light will be transport limitedly within the waveguide until the light reaches two sides of the waveguide.

Compared to a conventional solar collector, the self-absorbance of the fluorescent material may decrease when the fluorescent column is used. Conventionally, a fluorescent material may be mixed with a polymer material, or a fluorescent material may be coated onto a waveguide directly. The conventional methods will result in self-absorbance of the fluorescent material, and therefore photoelectric conversion will be seriously decreased.

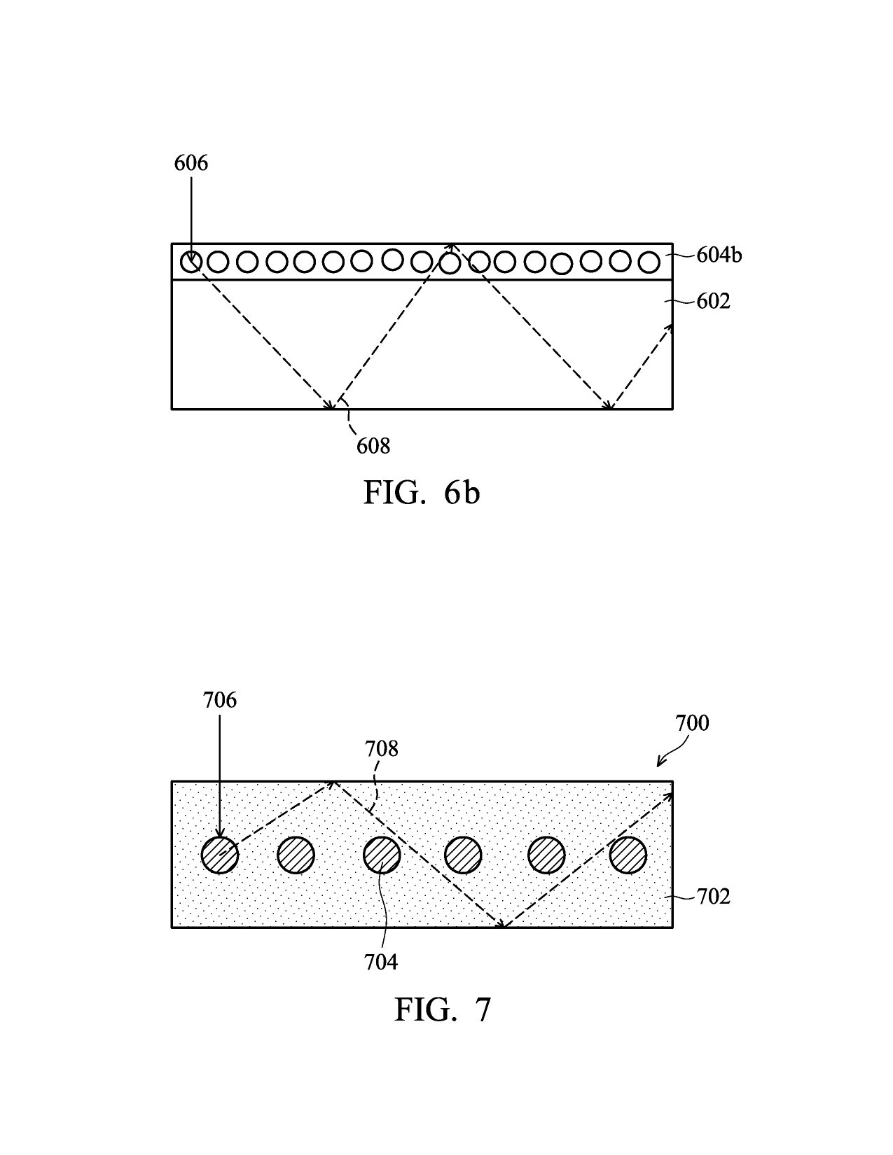

As shown in FIG. 6a, conventionally, when fluorescent bodies 604a are mixed directly with a gel material to form a waveguide 602, incident light 606 (solid line) will be absorbed by the fluorescent bodies 604a and excited light 608 (dot line) will be emitted. The excited light 608 will be limitedly directed within the waveguide to reach two sides of the waveguide. However, since the fluorescent bodies 604a are evenly dispersed in the waveguide 602, the excited light 608 will repeatedly pass through the fluorescent bodies 604a during total reflection. Therefore, the excited light 608 will be repeatedly re-absorbed by the fluorescent bodies 604a, resulting in energy loss.

In addition, when a fluorescent material 604a is coated onto a waveguide 602 directly, self-absorbance of the fluorescent material may be slightly reduced, as there is no fluorescent material inside of the waveguide. However, the excited light 608 (dot line) will still repeatedly pass through the fluorescent material 604a, and therefore, the excited light 608 will still be repeatedly re-absorbed by the fluorescent material 604a.

On the other hand, the fluorescent column embedded solar collector in FIG. 7 may prevent self-absorbance of the fluorescent material more effectively according to one embodiment. As shown in FIG. 7, incident light 706 (solid line) having a first wavelength will be absorbed by a wavelength conversion material in fluorescent columns 704. Then, excited light 708 (dot line) having a second wavelength will be emitted, wherein the first wavelength is smaller than the second wavelength. Since there is a substantial distance between each fluorescent column 704, the re-absorbance of the excited light 708 during the transmittance may be effectively avoided. Therefore, the light collecting ability of the solar collect 700 may be improved. In one embodiment, the distance between each fluorescent column may be at least 10 μm.

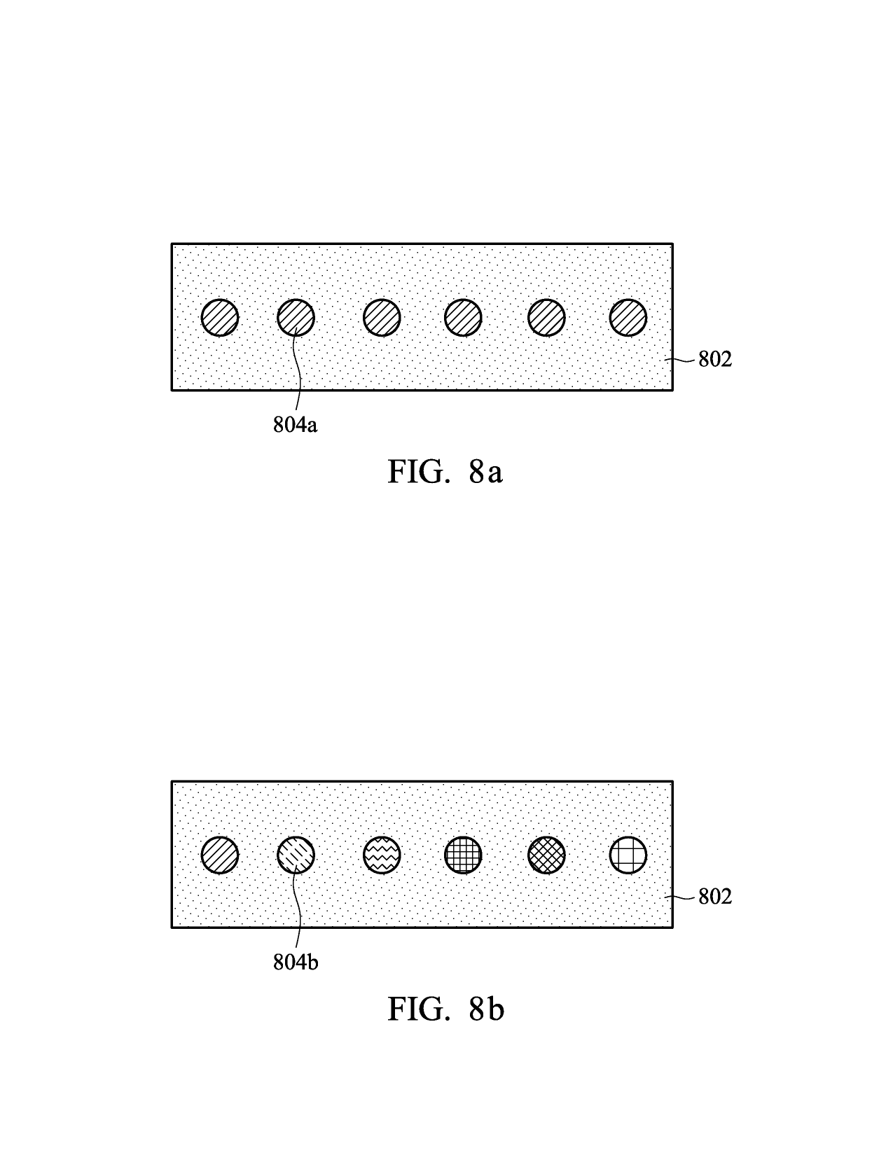

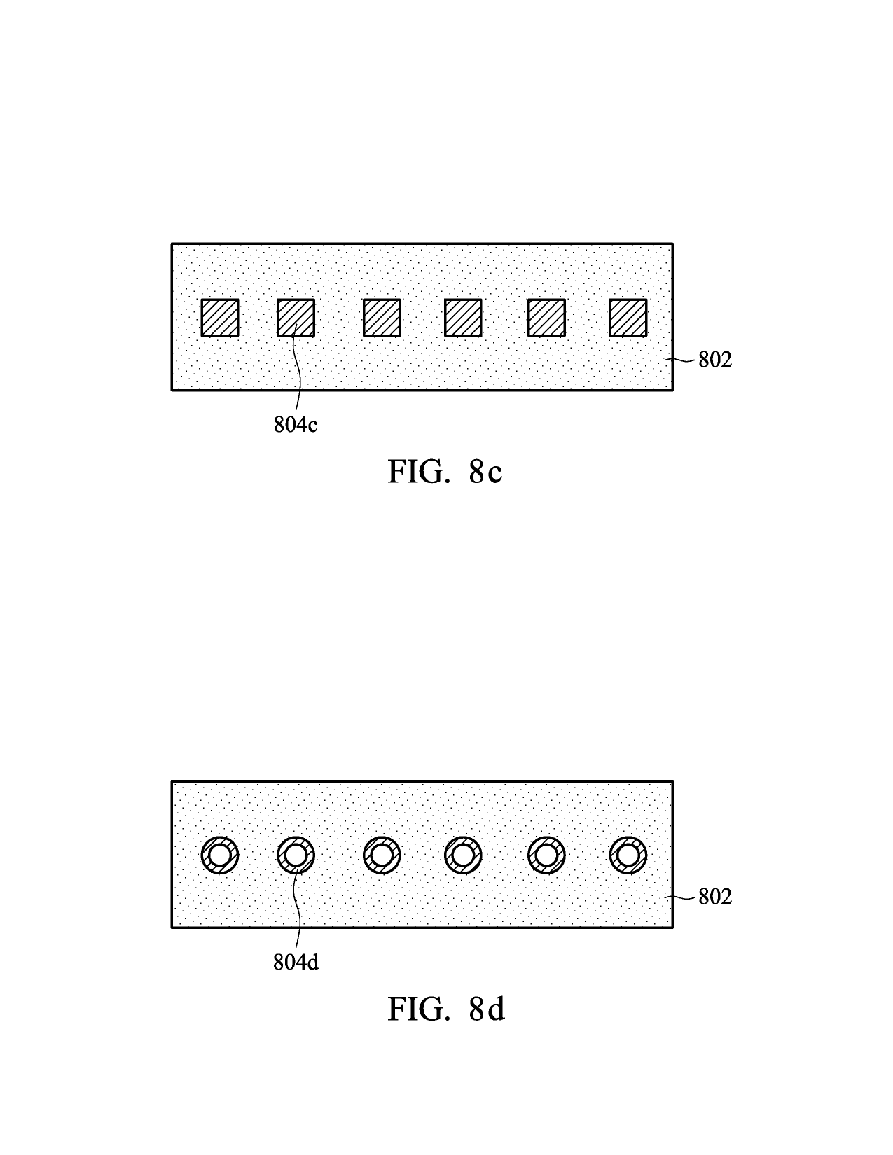

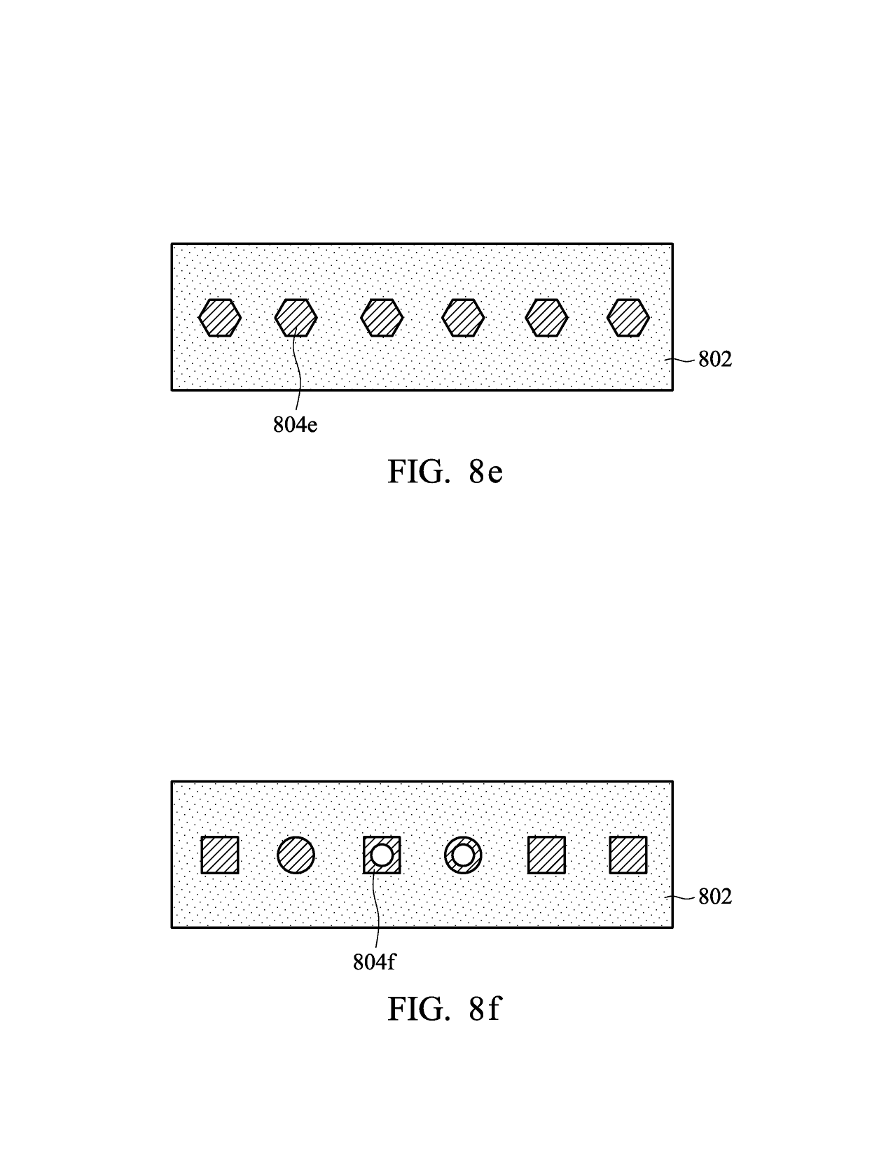

According to various embodiments, fluorescent columns in the waveguide may be designed to have different patterns. For example, as shown in FIGS. 8a to 8f, a waveguide 802 may comprise a plurality of fluorescent columns 804a-804f, wherein the plurality of fluorescent columns may have the same fluorescent material (as shown in FIG. 8a) or various fluorescent materials (as shown in FIG. 8b). In addition, the shapes of the plurality of fluorescent columns may comprise cylinders (such as 804a and 804b), hollow cylinders (such as 804d), rectangular cylinders (such as 804c), hollow rectangular cylinders (such as 804f), polygons (such as 804e), or combinations thereof.

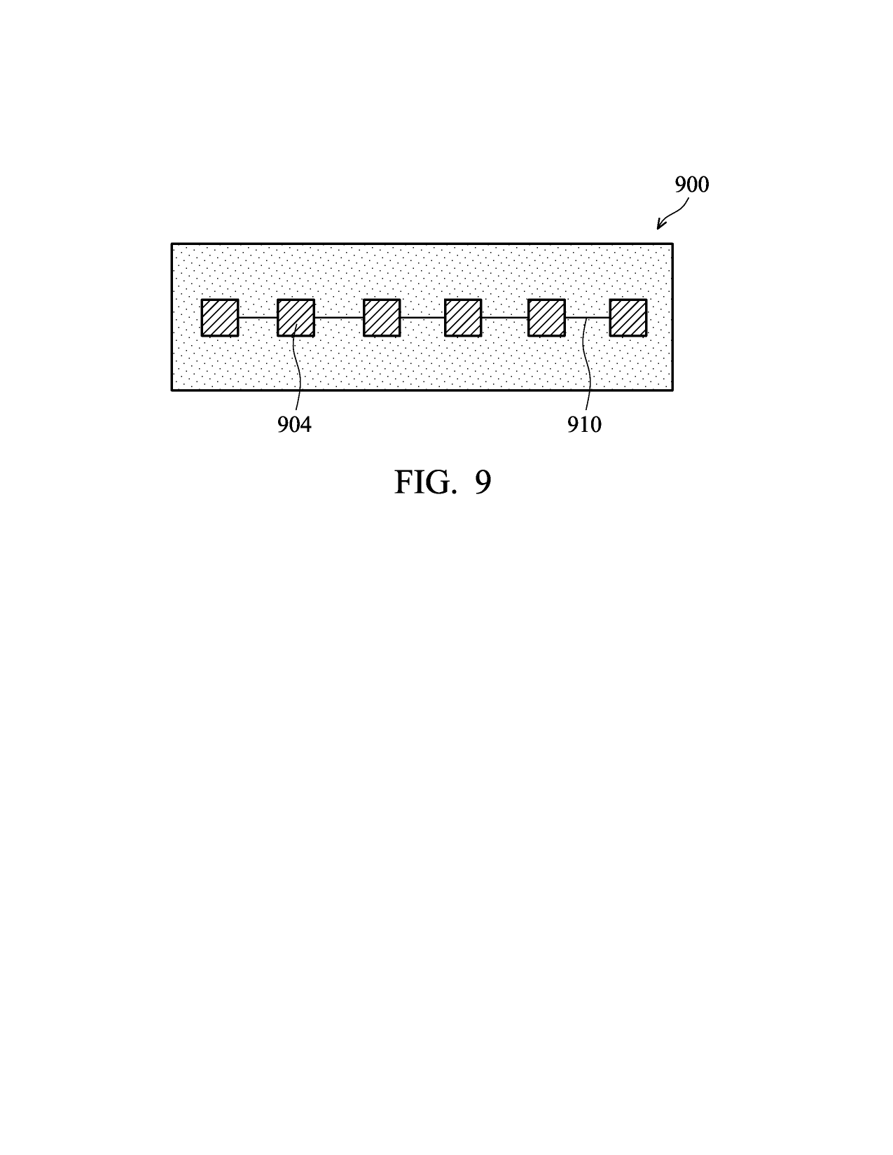

According to another embodiment, as shown in FIG. 9, each fluorescent column 904 may be connected by a continuous film 910. A thickness of the continuous film 910 is very thin. For example, the thickness of the continuous film 910 is of between 50 nm and 100 nm. Therefore, the light collecting efficiency of the solar collector will not be affected by the continuous film 910, but the manufacturing process of the solar collector 900 may be simplified. In other words, in the solar collector 900, the incident light is stilled converted by the fluorescent column 904 instead of the continuous film 910, and the continuous film 910 is thin enough that it can still avoid the self-absorbance of the fluorescent material. Therefore, the solar collector can have good transmittance as required.

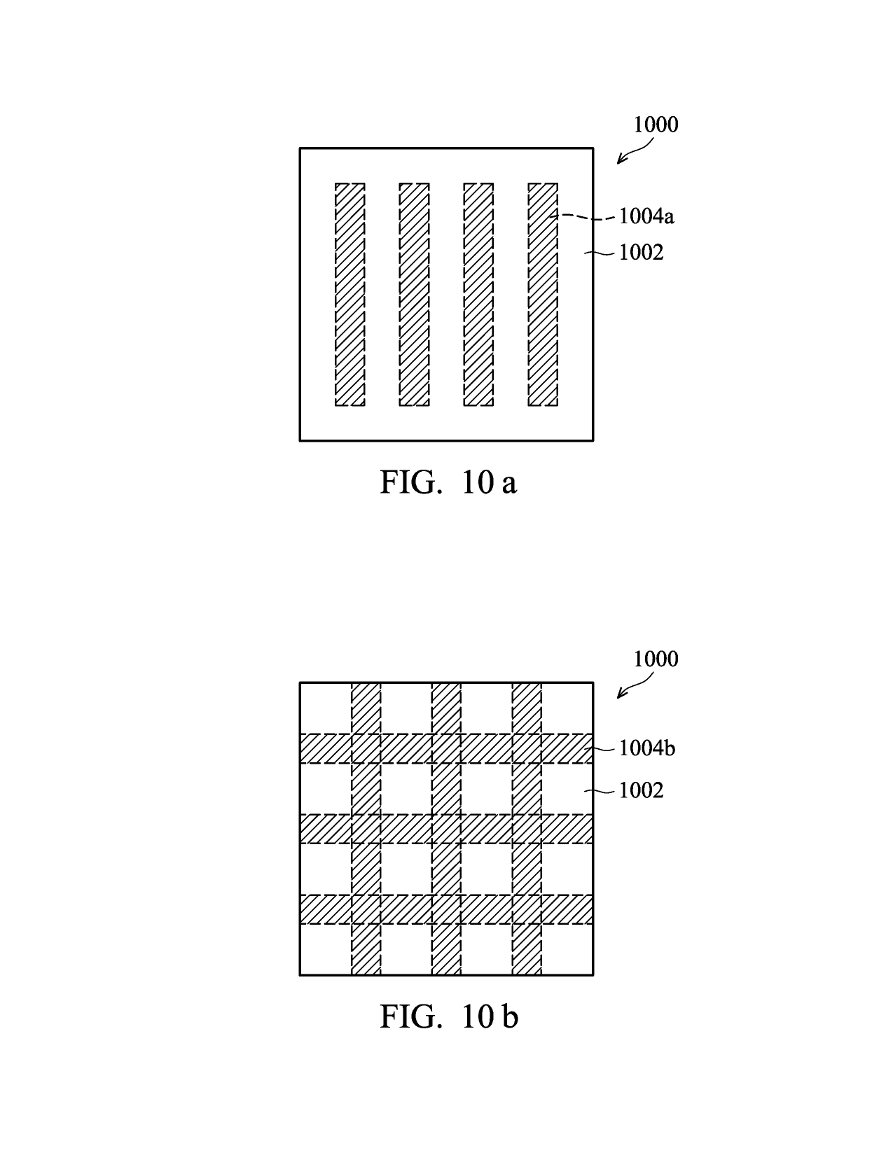

FIG. 10 illustrates a fluorescent column embedded solar collector according to one embodiment. As shown in FIGS. 10a-10b, a solar collector 1000 may have fluorescent columns forming a specific shape in the waveguide, such as a palisade shape (1004a) or a web shape (1004b). In some embodiments, the solar collector 1000 may be transparent. Since it is difficult for human eyes to recognize a size smaller than 100 μm (for example, human eyes may see a circle as a dot and a band as a line when the image is too small), the width of the fluorescent columns may be adjusted to be difficult for human eyes to recognize, and the transmittance of the solar collector may be improved (especially compared to the solar collectors having a flat fluorescent material coating). According to one embodiment, a width of the fluorescent column is between 10 μm and 100 μm. When the width of the fluorescent column is too large, the pattern of the fluorescent columns may be recognized by human eyes. When the width of the fluorescent column is too small, the manufacturing process may be difficult and costs increase.

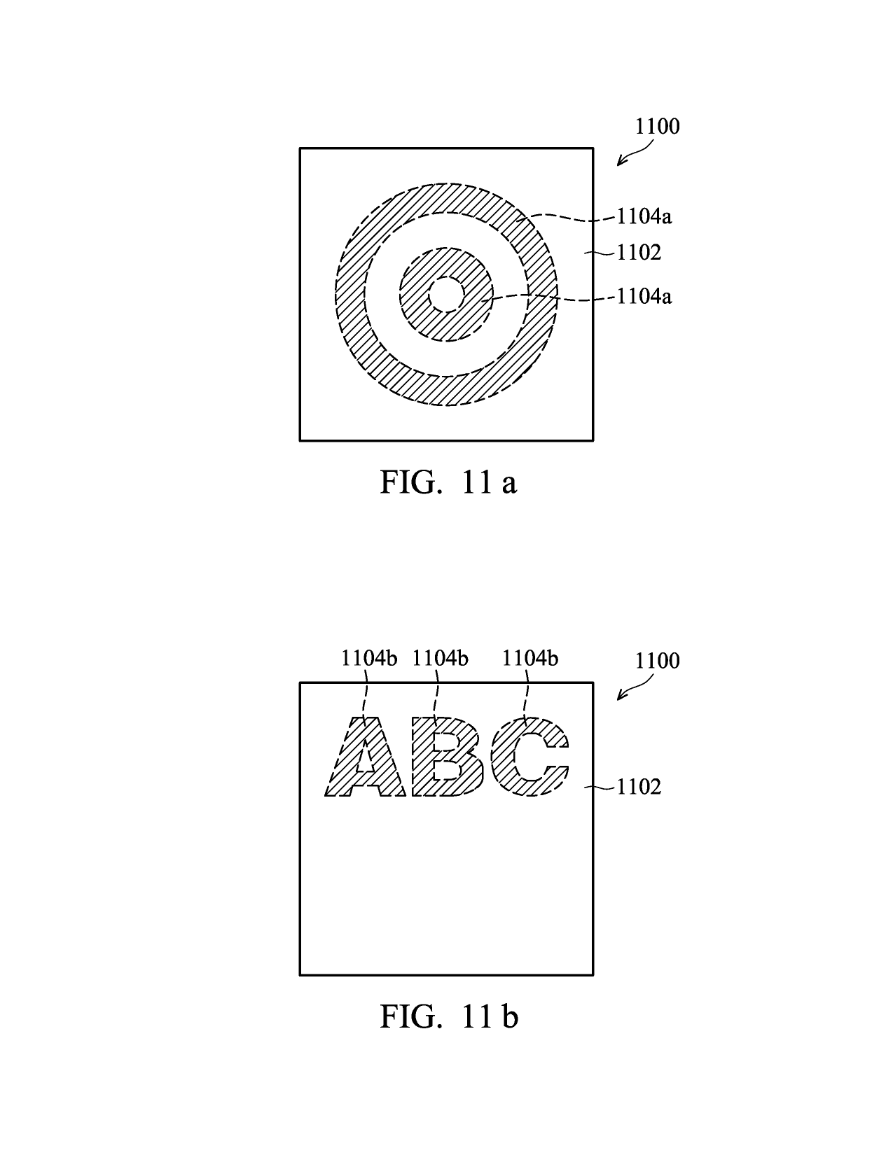

According to some other embodiments, the fluorescent columns may be formed in different colors. Therefore, the fluorescent columns may be designed to show different patterns or shapes in the waveguide, such as a palisade shape, a web shape, a pattern, a letter, a symbol, or combinations thereof. As shown in FIGS. 11a-11c, in the solar collector 1100, the waveguide 1102 may comprise concentric circles formed of fluorescent columns 1104a, letters formed of fluorescent columns 1104a, or other patterns formed of fluorescent columns 1104c₁ and 1104c₂. In addition, as shown in FIG. 11c, a plurality of fluorescent columns 1104c₁ and 1104c₂ may comprise different fluorescent materials to show different colors. In the embodiments, a width of the fluorescent column may be larger than 100 μm, wherein the patterns can be recognized by human eyes. The solar collectors may be used as commercial boards or the like. Moreover, since the patterns are formed by embedded fluorescent columns (i.e. the fluorescent columns still have a distance between each other as shown in FIG. 5), the solar collectors can still have low self-absorbance as described previously.

When the thickness of the fluorescent column is thinner or when the fluorescent column contains less fluorescent material, the fluorescent column may be transparent or be in a lighter color in the waveguide. On the other hand, when the thickness of the fluorescent column is thicker or when the fluorescent column contain more fluorescent material, the fluorescent column may show a darker color. Therefore, the thickness and the fluorescent material concentration may be adjusted according to the required photoelectric conversion rate or required color.

The embedded fluorescent columns described above may comprise at least one wavelength conversion material. The wavelength conversion material may be any known or future developed wavelength conversion material. According to one embodiment, the wavelength conversion material may comprise the dye-labeled polymer described previously, or the wavelength conversion material containing the dye-labeled polymer described previously. According to another embodiment, the wavelength conversion material may comprise fluorescent powder, organic fluorescent dye, polymer fluorescent material, inorganic fluorescent material, quantum dot fluorescent material, hybrid fluorescent material, phosphorescence powder, dye, or combinations thereof. However, it is noted that the wavelength conversion materials are merely examples, and the scope of the disclosure is not intend to be limiting.

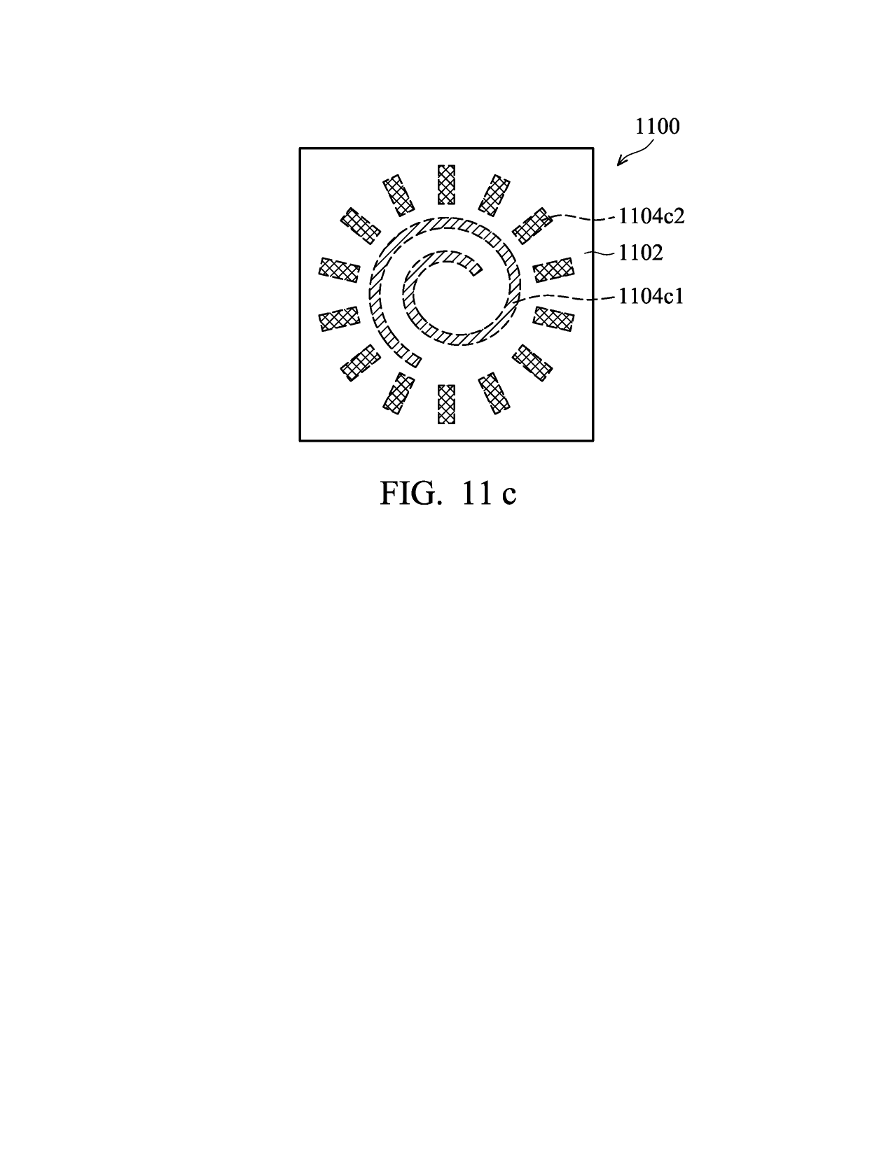

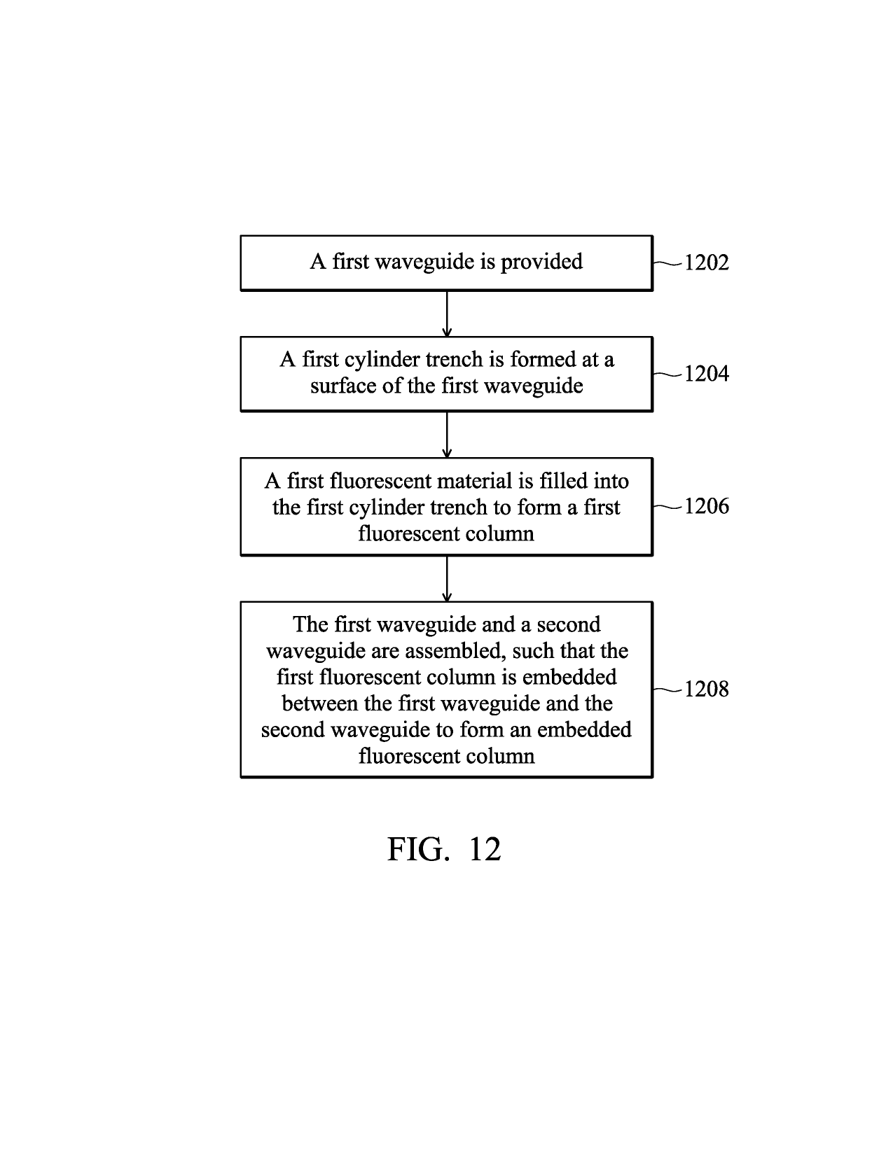

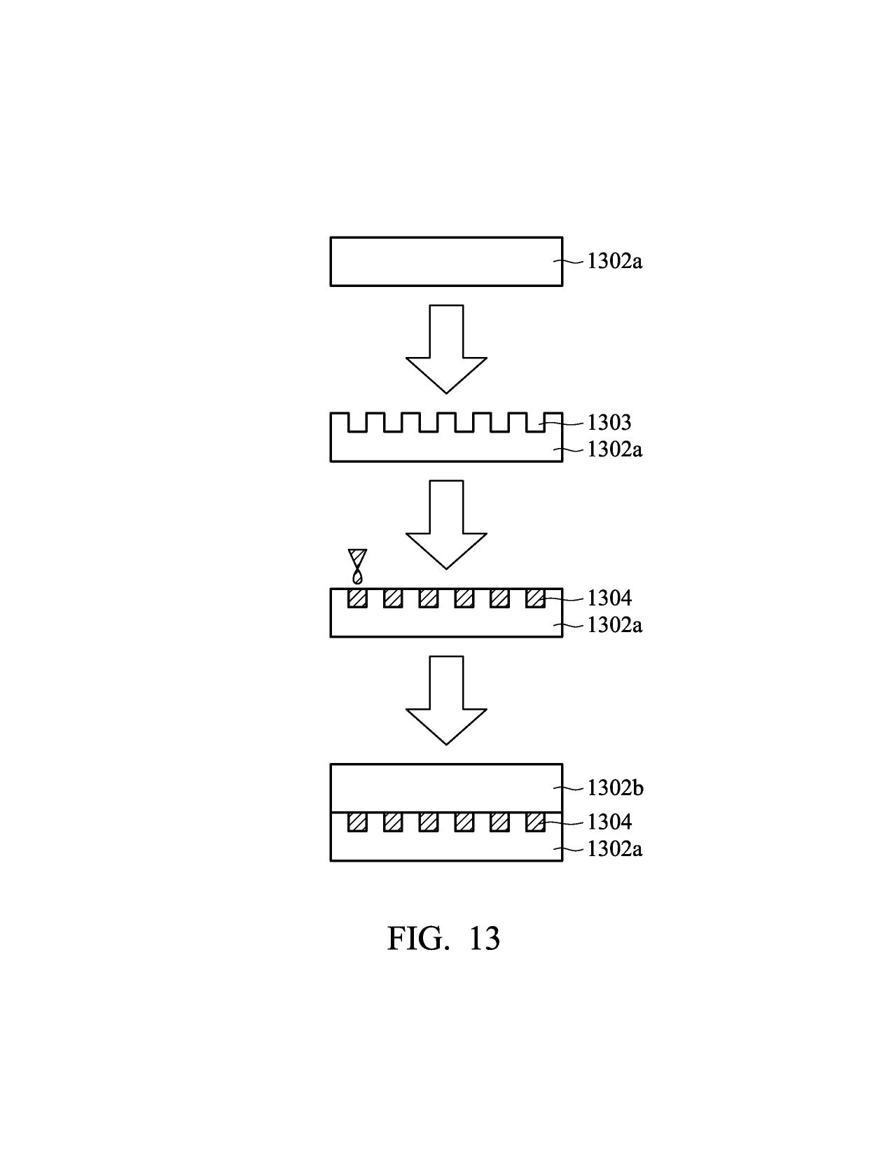

FIGS. 12 and 13 illustrate a manufacturing flowchart of a fluorescent column embedded solar collector and cross sections of the fluorescent column embedded solar collector at various manufacturing stages according to one embodiment. In step 1202, a first waveguide 1302a is provided. In step 1204, a first cylinder trench 1303 is formed at a surface of the first waveguide 1302a, such that an extension direction of the first cylinder trench 1303 is parallel to the main surface of the waveguide 1302a. The first cylinder trench 1303 may be formed by stamping, etching, laser printing, or combinations thereof. In step 1206, a first fluorescent material is filled into the first cylinder trench 1303 to form a first fluorescent column 1304. In step 1208, the first waveguide 1302a and a second waveguide 1302b are assembled, wherein the first fluorescent column 1304 is embedded between the first waveguide 1302a and the second waveguide 1302b to form an embedded fluorescent column 1304. It is noted that a shape of the cross section of the fluorescent column may be a circle or a paragon according to various embodiments, and the scope of the disclosure is not intended to be limiting.

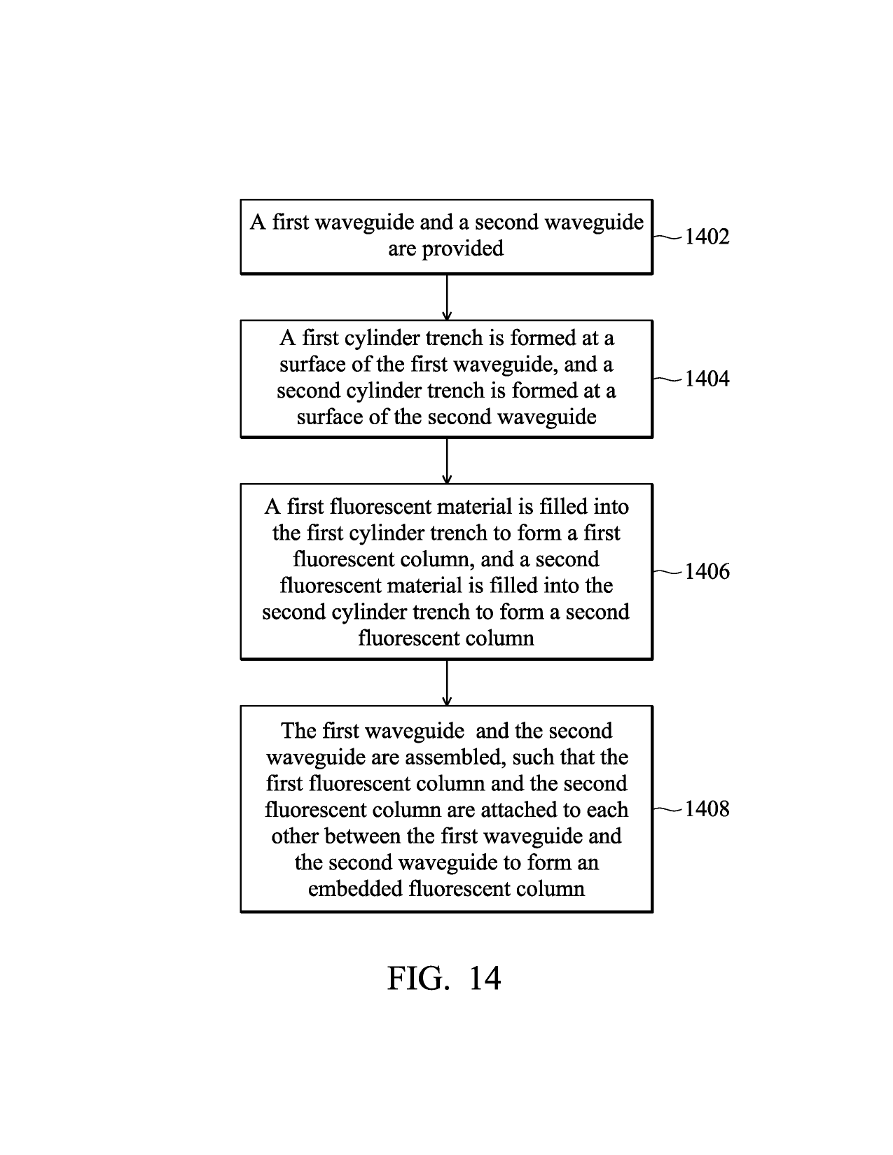

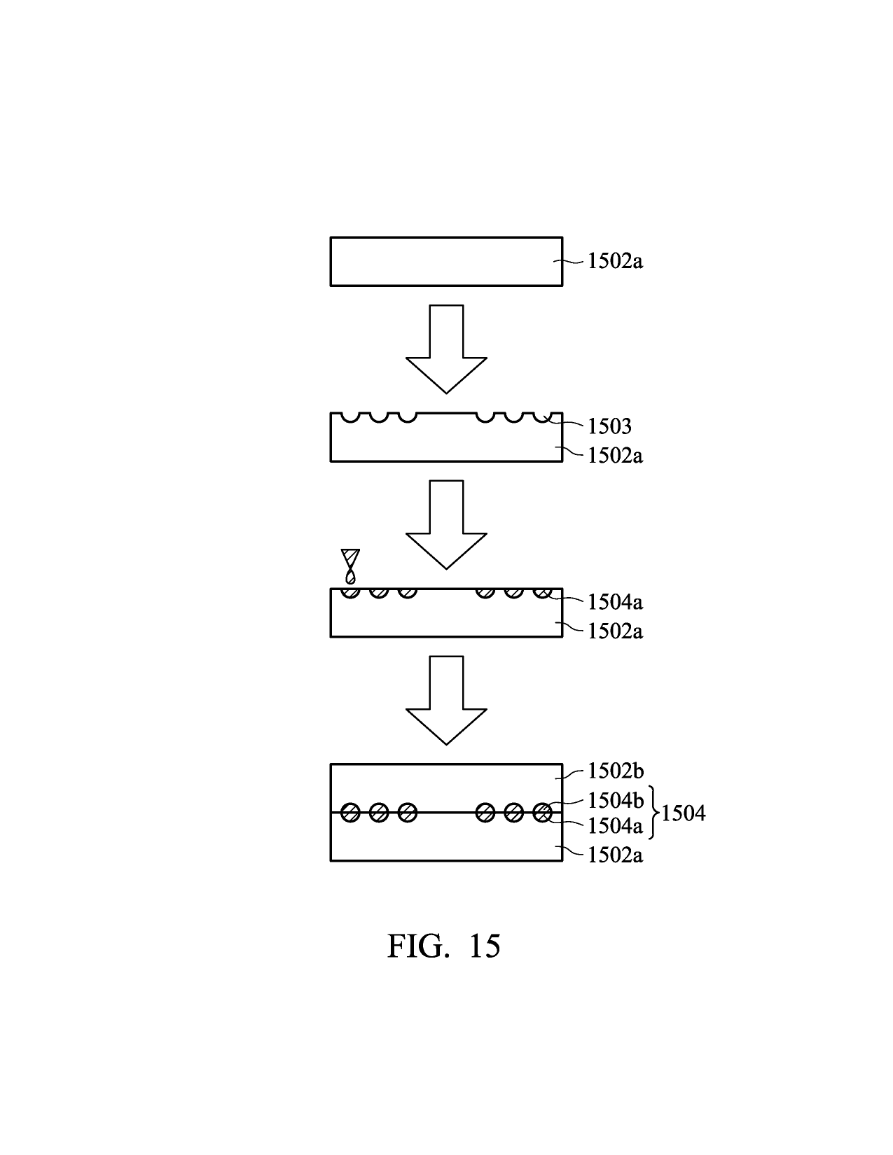

FIGS. 14 and 15 illustrate a manufacturing flowchart of a fluorescent column embedded solar collector and cross sections of the fluorescent column embedded solar collector at various manufacturing stages according to another embodiment. In step 1402, a first waveguide 1502a and a second waveguide 1502b are provided. In step 1404, a first cylinder trench 1503 is formed at a surface of the first waveguide 1502a, and a second cylinder trench is formed at a surface of the second waveguide 1502b. In step 1406, a first fluorescent material is filled into the first cylinder trench 1503 to form a first fluorescent column 1504a, and a second fluorescent material is filled into the second cylinder trench to form a second fluorescent column 1504b. In step 1408, the first waveguide 1502a and the second waveguide 1502b are assembled, wherein the first fluorescent column 1504a and the second fluorescent column 1504b are attached to each other between the first waveguide 1502a and the second waveguide 1502b to form an embedded fluorescent column 1504. As shown in FIG. 15, the first cylinder trench 1503 may be a recess having a semi-circular cross section, wherein the first fluorescent material filled in the trench will form a first fluorescent column 1504a having a semi-circular cross section. Next, the process can be repeated to form the second waveguide 1502b having the second fluorescent column 1504b. Then, the first waveguide 1502a and the second waveguide 1502b are assembled, wherein the first fluorescent column 1504a and the second fluorescent column 1504b are attached to each other between the first waveguide 1502a and the second waveguide 1502b to form an embedded fluorescent column 1504 with a circular cross section. It is noted that a shape of the cross section of the fluorescent column may also be rectangular or a paragon according to various embodiments, and the scope of the disclosure is not intended to be limiting.

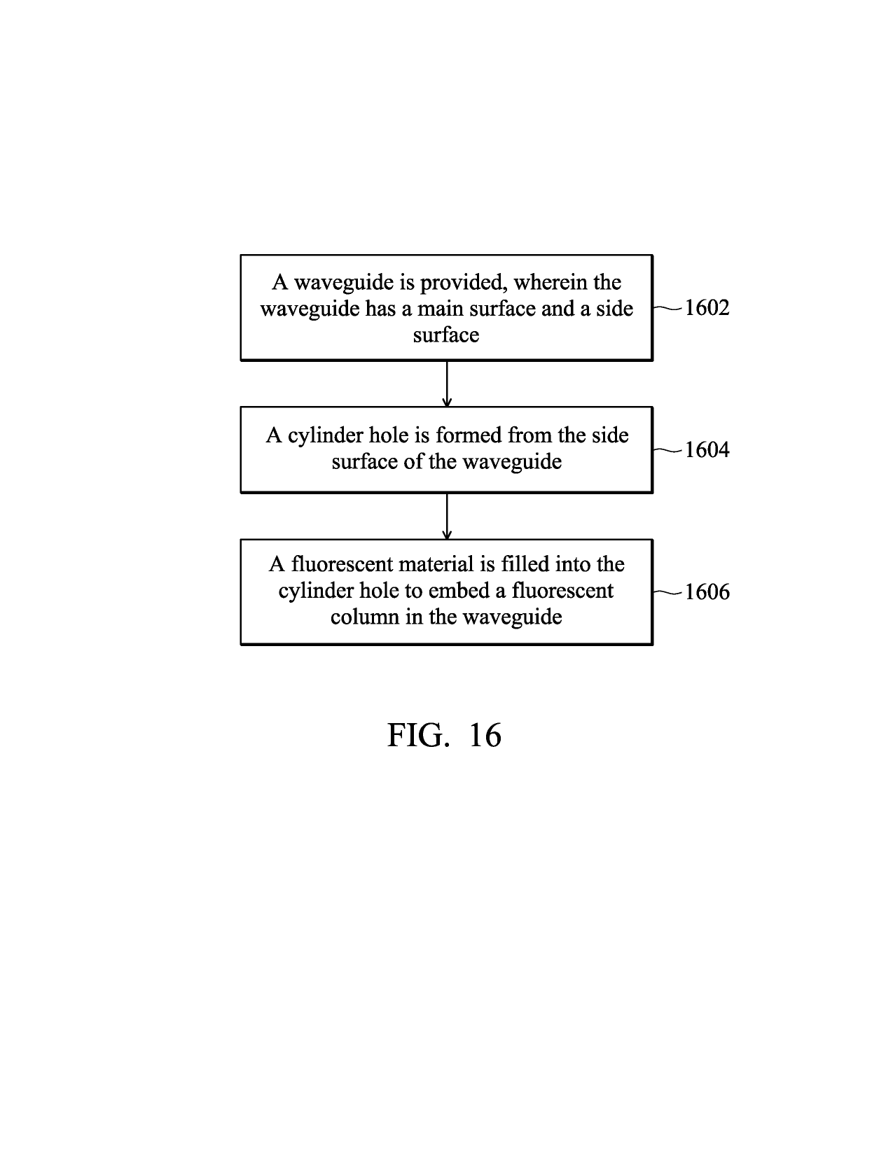

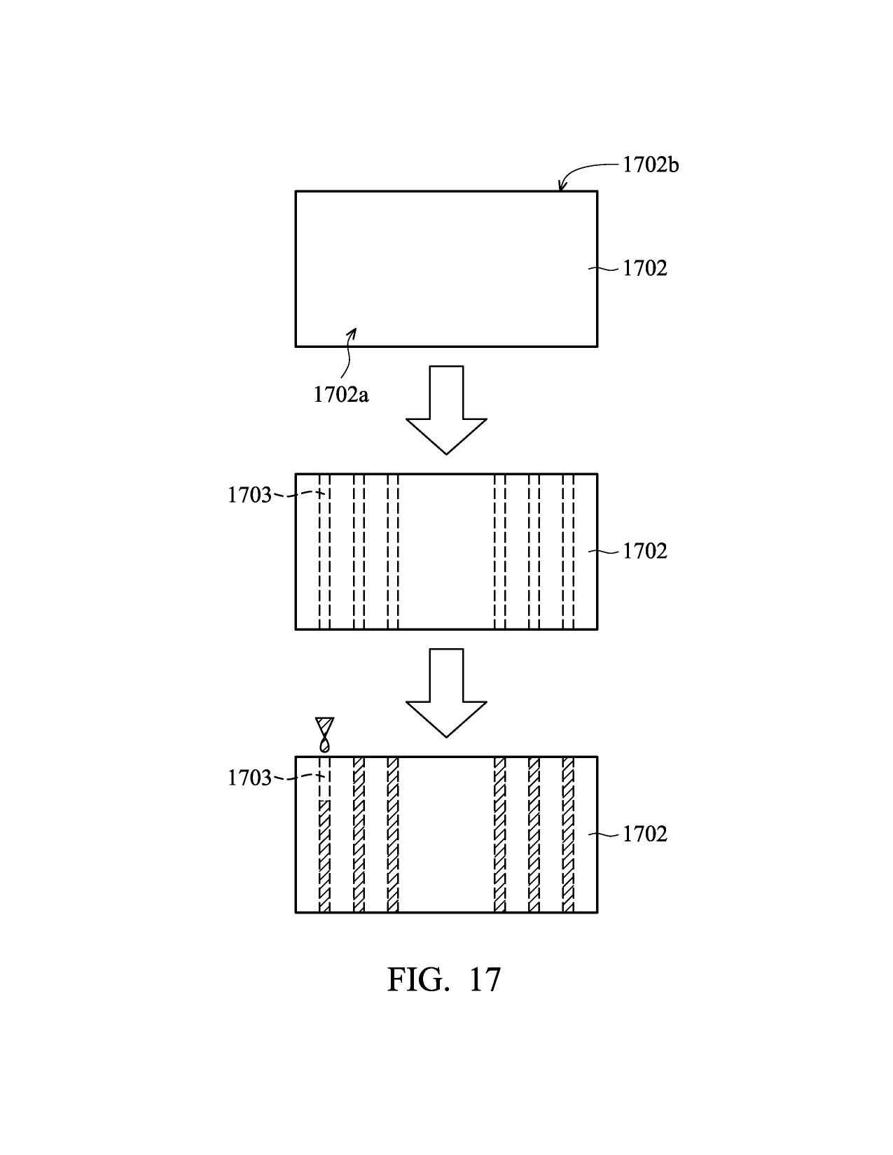

FIGS. 16 and 17 illustrate a manufacturing flowchart of a fluorescent column embedded solar collector and cross sections of the fluorescent column embedded solar collector at various manufacturing stages according to still another embodiment. In step 1602, a waveguide 1702 is provided, wherein the waveguide 1702 has a main surface 1702a and a side surface 1702b. In step 1604, a cylinder hole 1703 is formed from the side surface 1702b of the waveguide 1702, wherein the cylinder hole 1703 extends into the waveguide 1702. In one embodiment, the cylinder hole may be formed by a micrometer level drilling process, such as laser drilling, ion beam drilling, or combinations thereof. In step 1606, a fluorescent material is filled into the cylinder hole 1703 to embed a fluorescent column 1704 in the waveguide 1702. It is noted that although the cylinder hole 1703 passes through the waveguide 1702 in FIG. 17, the cylinder hole may not pass through the waveguide according to other embodiments. In addition, according to another embodiment, a shape of the cross section of the cylinder hole 1703 may be rectangular or a paragon, and the scope of the disclosure is not intended to be limiting.

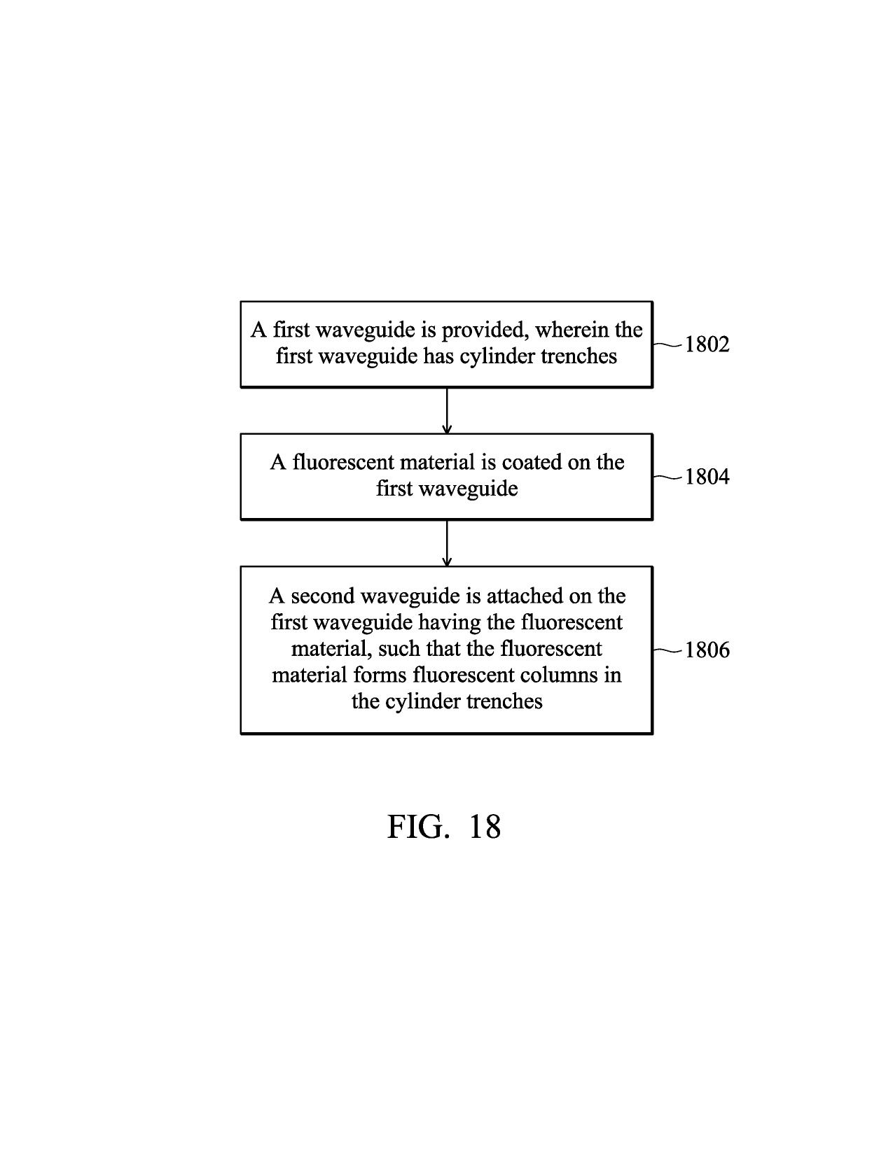

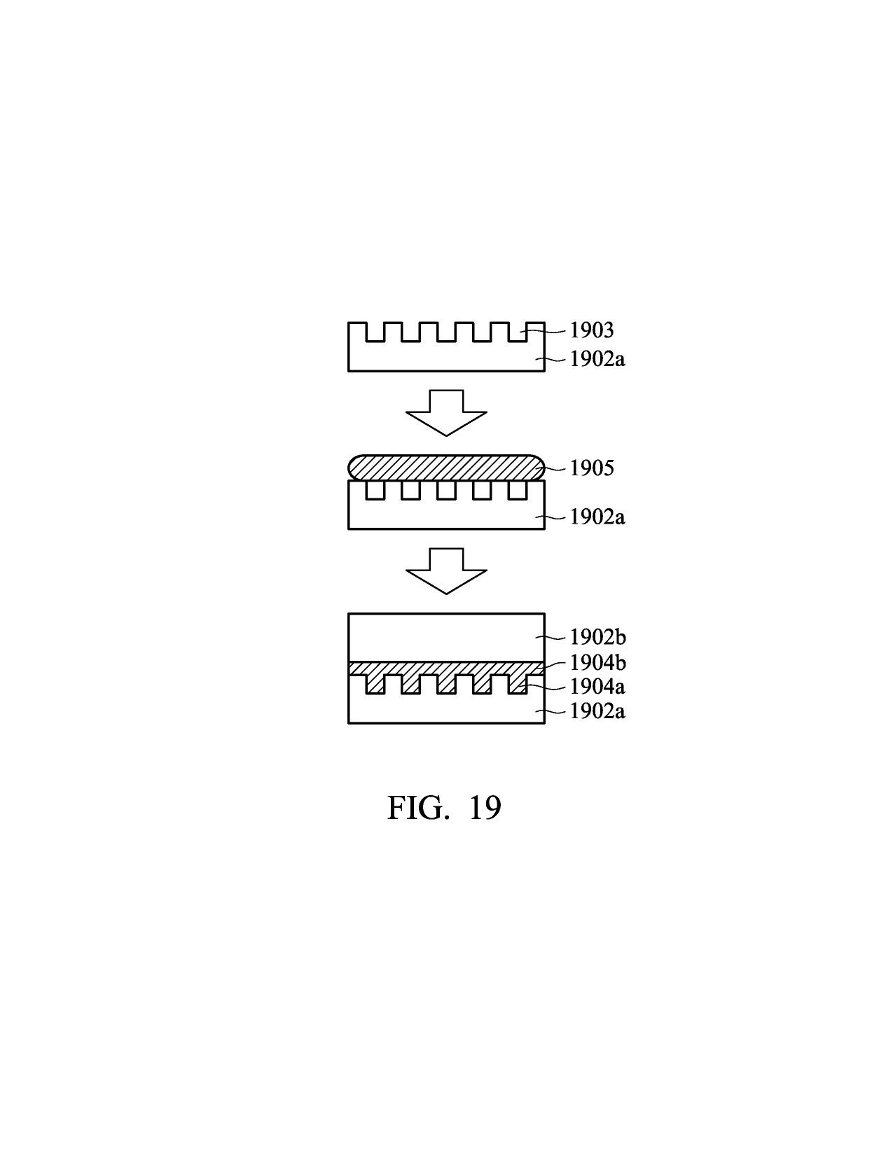

FIGS. 18 and 19 illustrate a manufacturing flowchart of a fluorescent column embedded solar collector and cross sections of the fluorescent column embedded solar collector at various manufacturing stages according to still another embodiment. In step 1802, a first waveguide 1902a is provided, wherein the first waveguide 1902a has cylinder trenches 1903. In step 1804, a fluorescent material 1905 is coated on the first waveguide 1902a. In step 1806, a second waveguide 1902b is attached on the first waveguide 1902a having the fluorescent material 1905, wherein the fluorescent material 1905 forms fluorescent columns 1904a in the cylinder trenches 1903. In addition, each fluorescent column 1904a is connected by a continuous film 1904b. Reference may be made to U.S. Pat. No. 6,797,090B2 for methods for manufacturing the embedded fluorescent columns with the continuous form. According the method described above, the resulting continuous film can be so thin that the transmittance of the solar collector may not be affected and the self-absorbance of the fluorescent material can still be reduced. The thickness of the continuous film may be between 50 nm and 100 nm according to one embodiment.

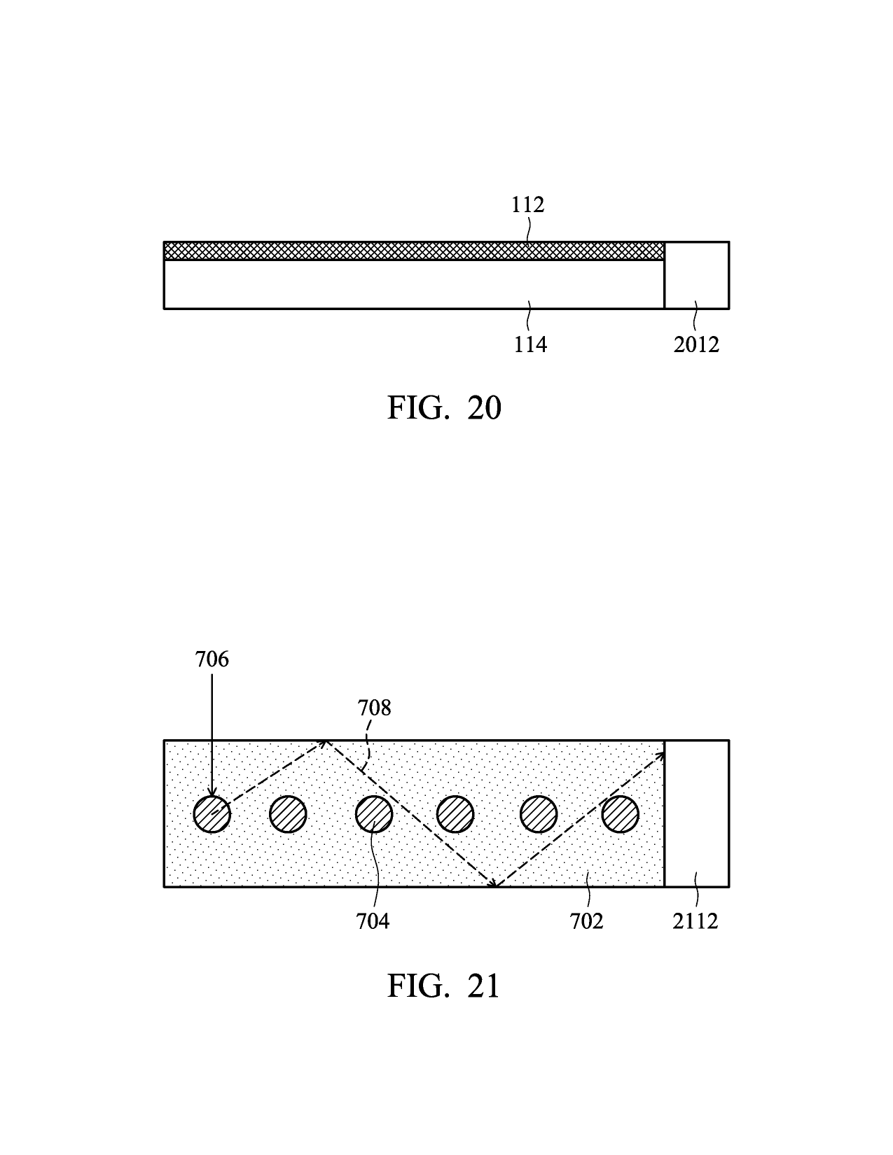

FIG. 20 illustrates a solar cell module according to one embodiment. As shown in FIG. 20, a solar cell module may comprise the solar collector described in FIG. 1 and a solar cell 2012 optically coupled to the solar collector, such that light passing through the solar collector is collected at the solar cell to be converted into electricity. The solar cell 2012 may be disposed at one side of the waveguide 114, and the dye-labeled polymer in the wavelength conversion material 112 may be coated onto the waveguide 114. It is noted that other solar collectors described in the disclosure may also be used according to some other embodiments.

FIG. 21 illustrates a solar cell module according to another embodiment. As shown in FIG. 21, the solar cell module may comprise the solar collector described in FIG. 7 and a solar cell 2112 optically coupled to the solar collector, such that light passing through the solar collector is collected at the solar cell to be converted into electricity. The solar cell 2112 may be disposed at one side of the waveguide 702. When sunlight is incident into the solar collector, the incident light 706 (solid line) having a shorter wavelength will be converted into excited light 708 (dot line) having a longer wavelength, and the energy gap of the solar cell 2112 can be matched. In addition, the excited light 708 converted by the embedded fluorescent column 704 will be limitedly directed in the waveguide to reach the solar cell 2112. According to one embodiment, the solar cell 2112 may comprise a circuit board or a solar cell chip, and therefore, the excited light 708 may be converted into electricity and may be used as an energy supply.

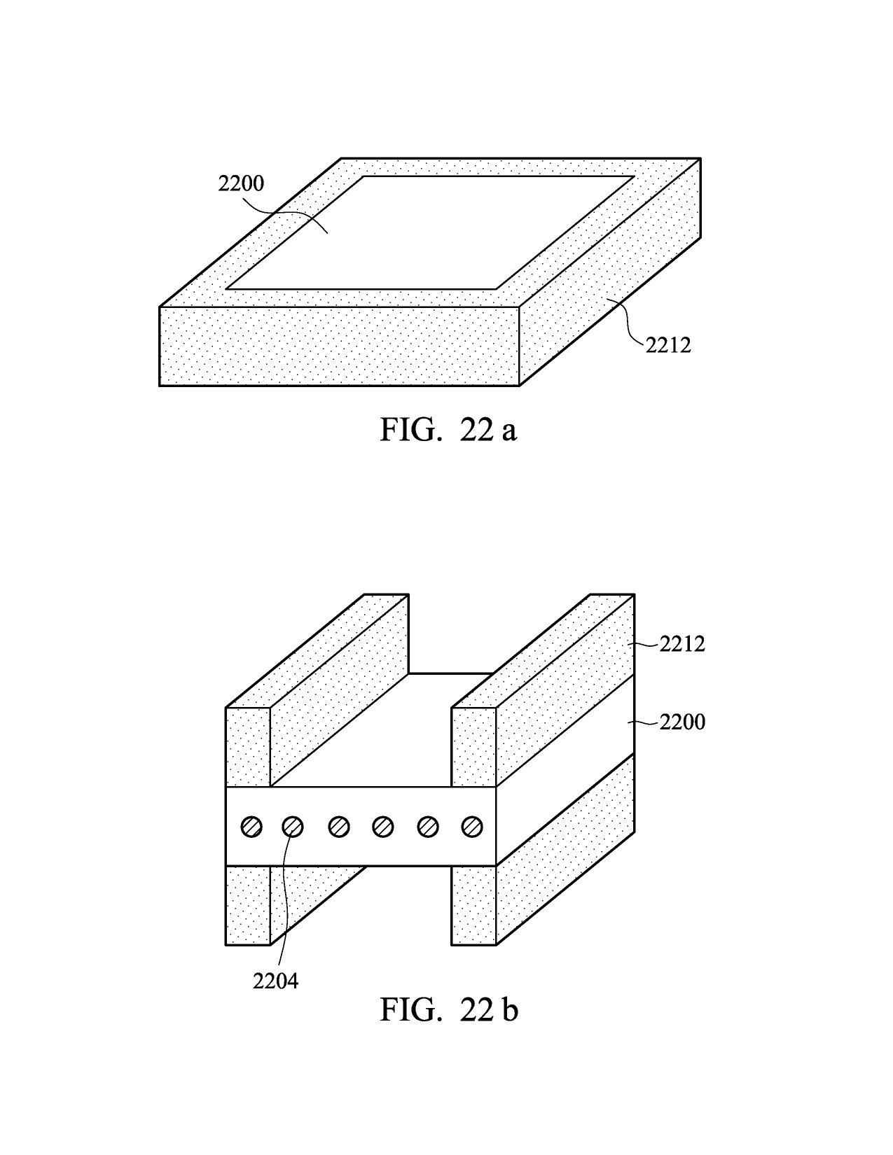

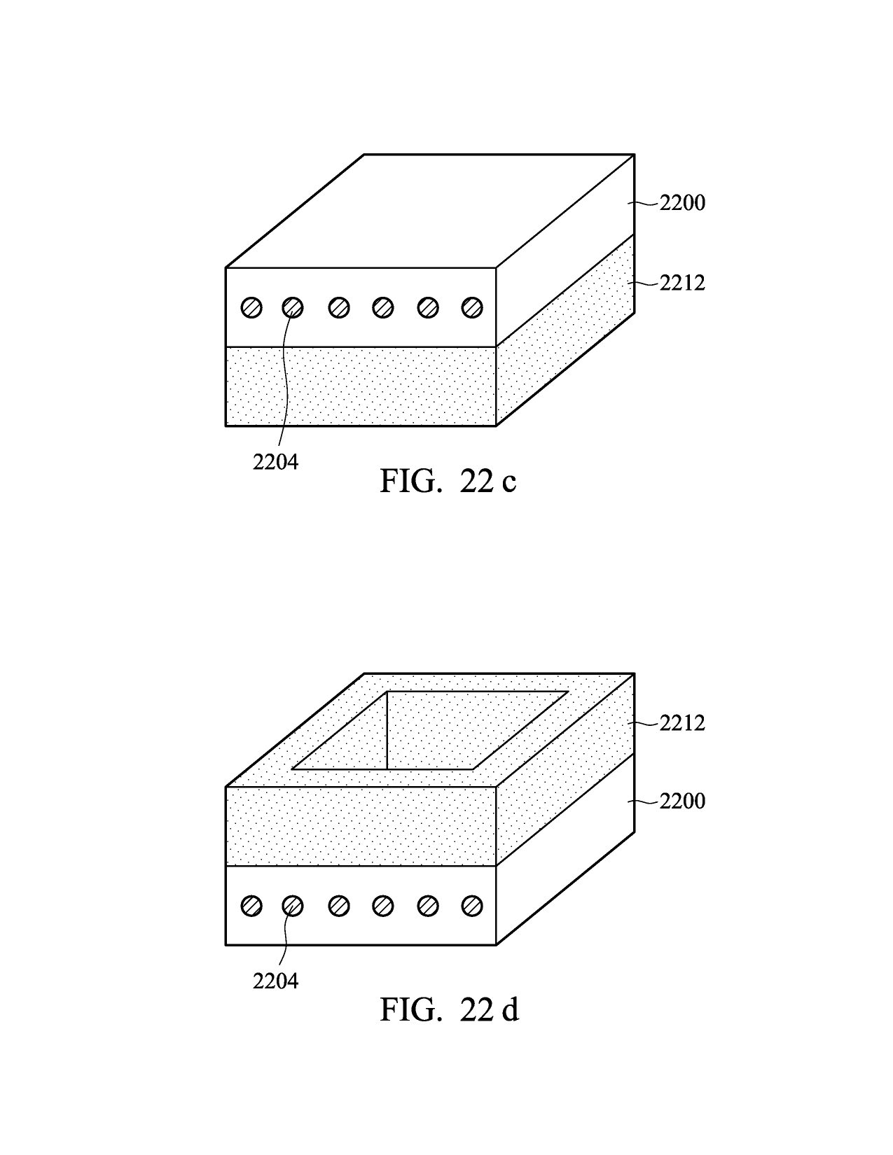

FIGS. 22a-22d illustrates solar cell modules using the solar collector in FIG. 7 according to various embodiments. As shown in FIGS. 22a-22d, the solar cell 2212 may be in a form of a band or a plate and may be disposed around or on the top or bottom of the solar collector 2200. Differences between the conventional solar cell modules and the solar cell modules in the embodiment may include:

(1) Transmittance and visibility: A conventional solar cell formed of silicon-based material usually has poor transmittance and cannot be used in applications requiring high transmittance and visibility. However, in the embodiments, the fluorescent column embedded solar collectors have high transmittance and visibility, and sunlight can be collected and directed to the solar cell by the fluorescent column embedded solar collector. Therefore, the solar collectors may be used in applications requiring high transmittance and visibility, such as a glass curtain outside of a building, windows of a car, or the like.

(2) Angle usability: A conventional solar cell may just absorb direct sunlight. Therefore, its photoelectric conversion rate is limited and it may be used on the roof of a building, most of the time. However, the fluorescent column embedded solar collectors according to various embodiments have fluorescent columns that can absorb anisotropic sunlight and then excited light will be emitted and directed with the waveguide. Therefore, the fluorescent column embedded solar collectors do not have to directly face the sun, but can still have a similar conversion rate. Therefore, the solar collectors may be used on places in addition to the roof of buildings, such as glass curtains on the outside of a building. If the fluorescent column embedded solar collectors are used on a large portion of the glass curtain to convert light into electricity, the electricity may be an alternative energy supply for the building. In addition, the fluorescent columns in the solar collectors can absorb some energy of the sun, and therefore, the temperature of the building may be decreased.

(3) Size: For a conventional solar cell, the photoelectric converting ability can be increased by increasing the concentration or the width of the fluorescent material. However, the increase of the concentration or the width may also result in serious self-absorbance of the fluorescent material. In other words, if the size of the fluorescent material increases, the photoelectric conversion rate will decrease accordingly. However, the fluorescent column embedded solar collectors according to various embodiments have a distance between each fluorescent column, and therefore, self-absorbance of the fluorescent material may be avoided. Therefore, a fluorescent column embedded solar collector can be manufactured with a larger size while still having a good photoelectric conversion rate.

(4) Color: A conventional solar cell is usually grey or blue. However, the fluorescent column embedded solar collectors according to various embodiments may contain different fluorescent materials which absorb light having different wavelengths and emit light having different wavelengths. Therefore, the fluorescent column embedded solar collectors may appear as various colors and can also be used as a decoration.

In addition, a fluorescent column embedded solar collector according to one embodiment may also be used on a flexible substrate, and be disposed on an umbrella, and then the solar collector can be connected to a solar cell to convert light into electricity.

The photoelectric conversion rate of a conventional solar cell formed of silicon-based material may be between 15% and 18%. As the size of the solar cell is reduced, the photoelectric conversion rate may also decrease. On the other hand, for the solar cell module according to various embodiments of the disclosure, a solar collector having a large surface can direct light into a solar cell having a small size. Therefore, the photoelectric conversion rate may be improved. In addition, a dye-labeled polymer having an adjustable absorbing/emitting wavelength may be used in the solar collector to match with the absorption range of the solar cell. For example, when the absorption range of a solar cell is between about 1.3V and 1.5V (700 nm-1100 nm), the dye-labeled polymer may be chosen to absorb light above 1.3V-1.5V and emit light about 1.3V-1.5V. On the other hand, a solar cell may be chosen to have an absorption range match with the fluorescent converting range of the dye-labeled polymer. For example, when a photo luminescence wavelength of the dye-labeled polymer is between 700 nm and 1100 nm, the solar cell may be formed of AsGa (having an energy gap of about 1.43 eV).

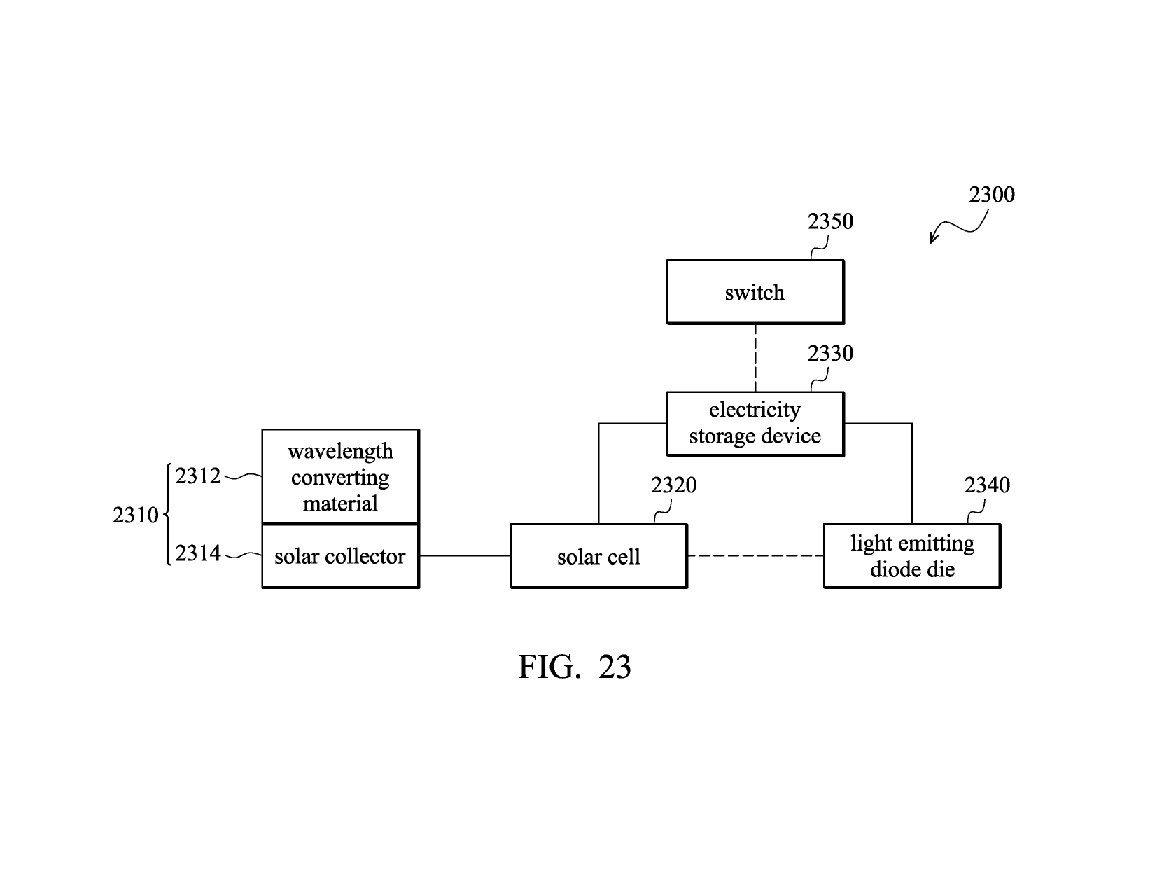

FIG. 23 illustrates a block diagram of an off-grid lamp 2300 according to one embodiment. The off-grid lamp 2300 comprises a solar collector 2310, a solar cell 2320, an electricity storage device 2330, and a light emitting diode die 2340. In various embodiments, the solar collector 2310 may be the solar collector having the dye-labeled polymer as shown in FIG. 1 or the solar collector having a fluorescent column embedded therein as shown in FIG. 7.

As shown in FIG. 23, according to one embodiment, the solar cell 2320 is optically coupled to the solar collector 2310. Therefore, when light passes through the solar collector 2310, the dye-labeled polymer will absorb light having a first wavelength and emit light having a second wavelength. The emitted light is directed into the solar cell 2320 through total reflection. Therefore, the dye-labeled polymer can be chosen to have an appropriate fluorescent wavelength converting range to match with the absorption range of the solar cell 2320.

After the light is collected by the solar collector 2310 and directed to the solar cell 2320, the solar cell 2320 will convert light into electricity. In addition, the electricity storage device, which is electrically connected to the solar cell 2320, will receive and store the electricity output from the solar cell 2320. The light emitting diode die 2340 is electrically connected to the electricity storage device 2330, and the electricity stored by the electricity storage device 2330 can be used by the light emitting diode die 2340. According to another embodiment, the off-grid lamp 2300 may further comprise a switch 2350 electrically connected to the electricity storage device 2330 to turn on and off the light emitting diode die 2340. According to still another embodiment, the light emitting diode die 2340 may be electrically connected to the solar cell 2320 directly.

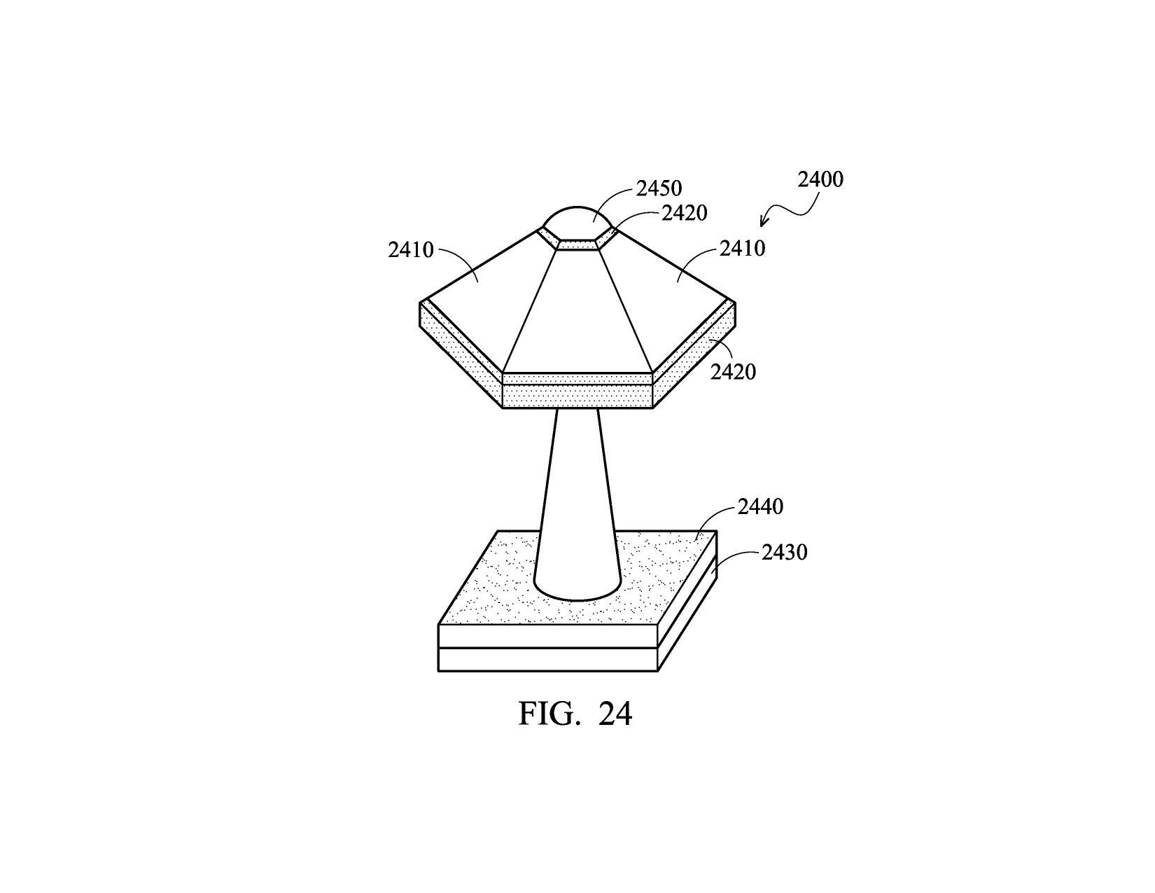

FIGS. 24-26 illustrate off-grid lamps according to various embodiments. As shown in FIG. 24, an off-grid lamp 2400 comprises a solar collector 2410, a solar cell 2420, an electricity storage device 2430, a light emitting diode die 2440, and a switch 2450. According to one embodiment, the solar collector 2310 may be the solar collector containing a dye-labeled polymer having a single color. According to another embodiment, the solar collector 2310 may be the solar collector having a fluorescent column embedded therein. The switch 2450 may be a touch sensing switch.

As shown in FIG. 24, the off-grid lamp 2400 comprises a large range of the solar collector 2410. Therefore, light coming from all directions can be directed to the solar cell 2420 by the collector 2410 effectively. In addition, the light emitting diode die 2440 can require a small amount of energy, and therefore, the electricity produced by the solar cell may be efficient for the light emitting diode die 2440 to turn on without using additional electricity.

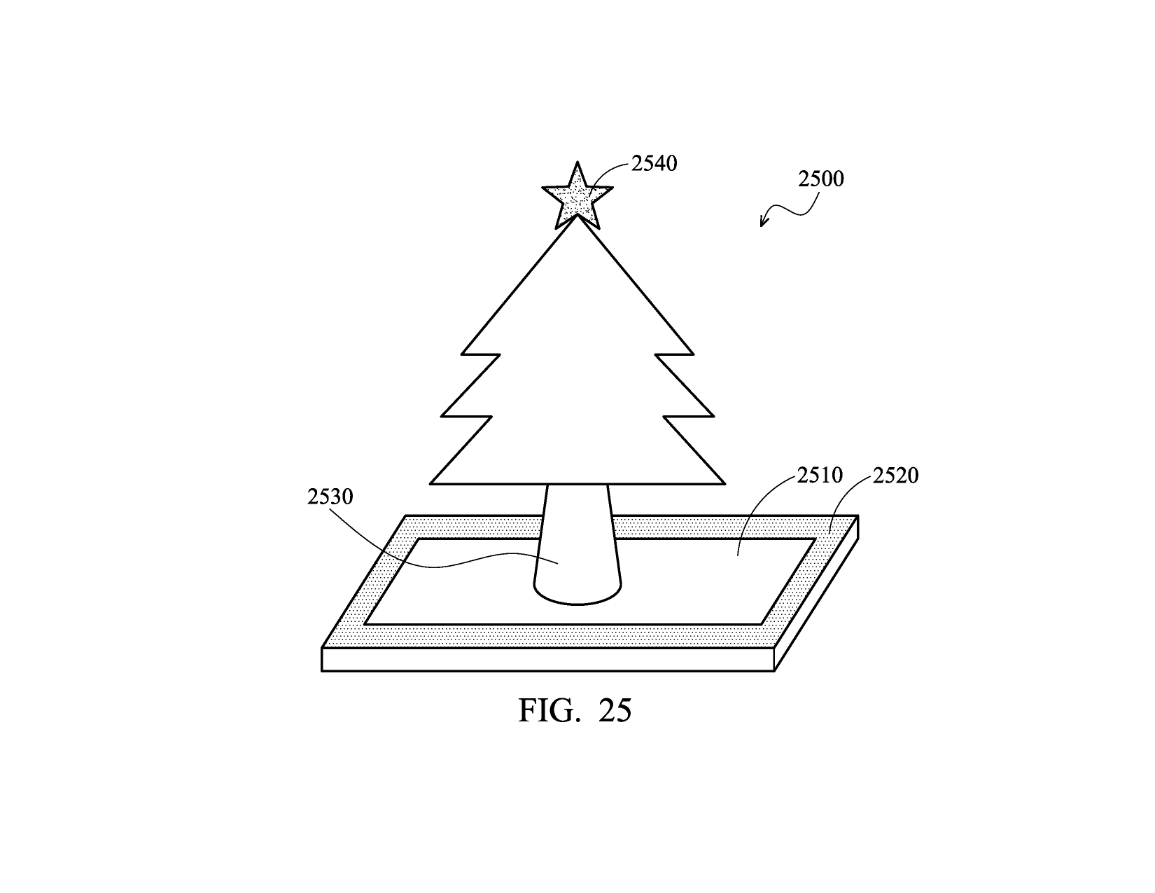

As shown in FIG. 25, an off-grid lamp 2500 comprises a solar collector 2510, a solar cell 2520, an electricity storage device 2530 (embedded inside the device), and a light emitting diode die 2440, wherein the light emitting diode die 2440 and the solar collector 2510 are disposed at different portions of the lamp. The off-grid lamp 2500 does not require additional electricity, and may be used in all kinds of applications found in everyday life, such as a Christmas tree, furniture, a tile, a window, a decoration, or the like. The applications may not only be convenient but also be eco-friendly.

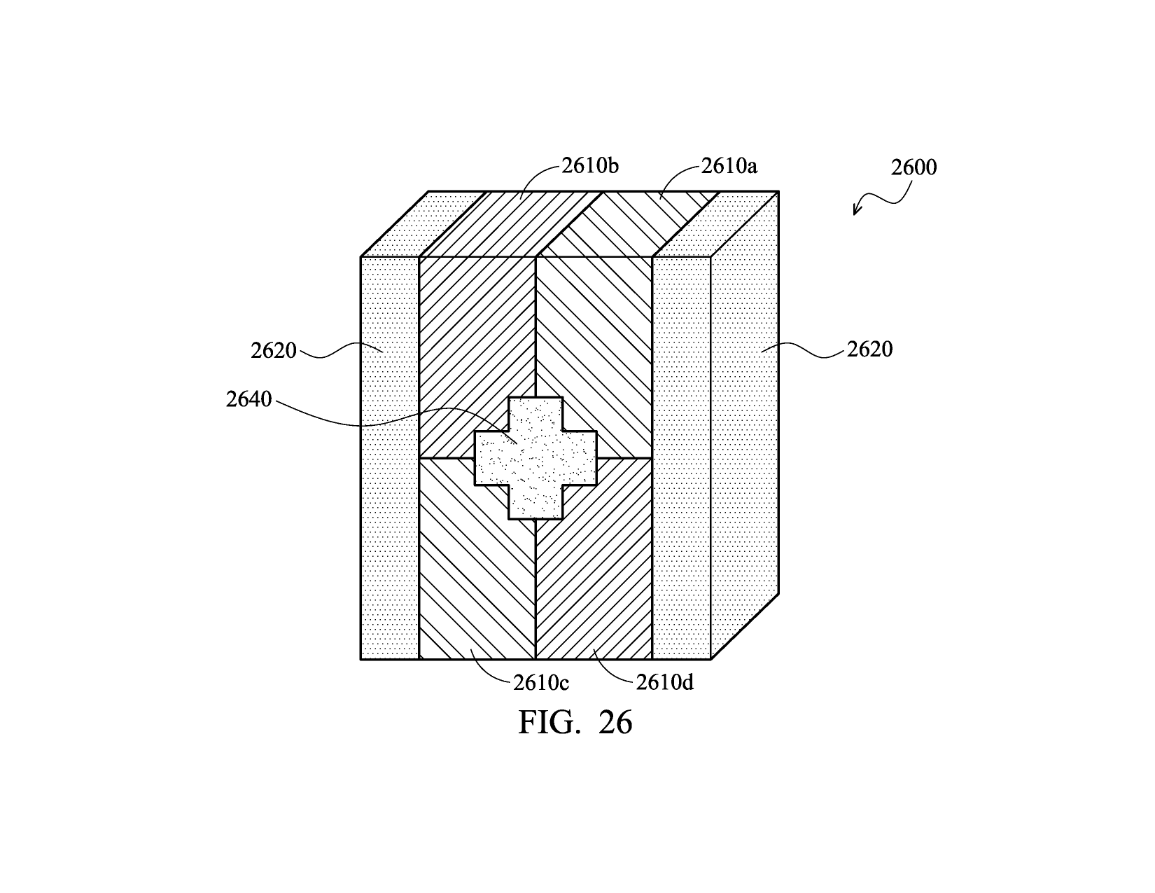

As shown in FIG. 26, an off-grid lamp 2600 comprises solar collectors 2610a-2610d, a solar cell 2620, an electricity storage device 2630, and a light emitting diode die 2640, wherein the light emitting diode die 2640 may be disposed onto the solar collectors. In addition, according to the embodiment, the solar collectors 2610a-2610d comprise more than one dye-labeled polymer, and the solar collectors 2610a-2610d are transparent. Therefore, the solar collectors 2610a-2610d show various colors and can be used as a decoration (such as stained glass). In addition, the colorful solar collectors can also absorb light having different wavelengths, and therefore the photoelectric conversion rate may also be improved.

According to one embodiment, the off-grid lamp containing a dye-labeled polymer may have the following features:

(1) Energy saving: A solar collector containing a dye-labeled polymer can convert sunlight into electricity. The electricity can be further used by a light emitting diode die (which can require a little amount of energy) so a lamp can be used without additional electricity.

(2) Colorful: By choosing different dye-labeled polymers, the solar collector can show various colors as required.

(3) Wide angle range: Light coming from all directions can be absorbed by the dye-labeled polymers and then be further directed to the solar cell. Therefore, applications are widely broadened.

(4) Energy recycling: A conventional silicon-based solar cell may just absorb direct light. However, a dye-labeled polymer can also absorb scattered light. Therefore, light coming from other lighting devices may also be used by the lamp.

### Example 1

### Synthesis of Dye-Labeled Polymer 2

A ring-opening polymerization is performed by reacting 50 moleε-caprolactone monomer and 1 mole 9-(hydroxymethyl) anthracene (containing —OH group) with 0.1 g of stannous 2-ethylhexanoate (as a catalyst) at 130° C. The reaction was continued for 8 hours. The resulting dye-labeled polymer had the following formula:

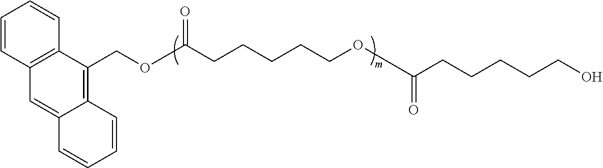

wherein m is 50.

### Example 2

### Solar Collector Containing the Dye-Labeled Polymer

The dye-labeled polymer of Example 1 and pure poly ethylene vinyl acetate were dissolved in toluene and stirred for 3 hours at room temperature. The wavelength conversion material containing 1% or 10% of the dye-labeled polymer was formed, and the wavelength conversion material was coated onto a glass substrate with a thickness of 1 cm to form a solar collector.

In addition, pure poly ethylene vinyl acetate and pyrene (conventional fluorescent material) were also mixed and dissolved in toluene and stirred for 3 hours at room temperature. The polymer solution containing 1% or 2% of pyrene was formed. The polymer solution was coated onto a glass substrate with a thickness of 1 cm to form a solar collector as a comparative example.

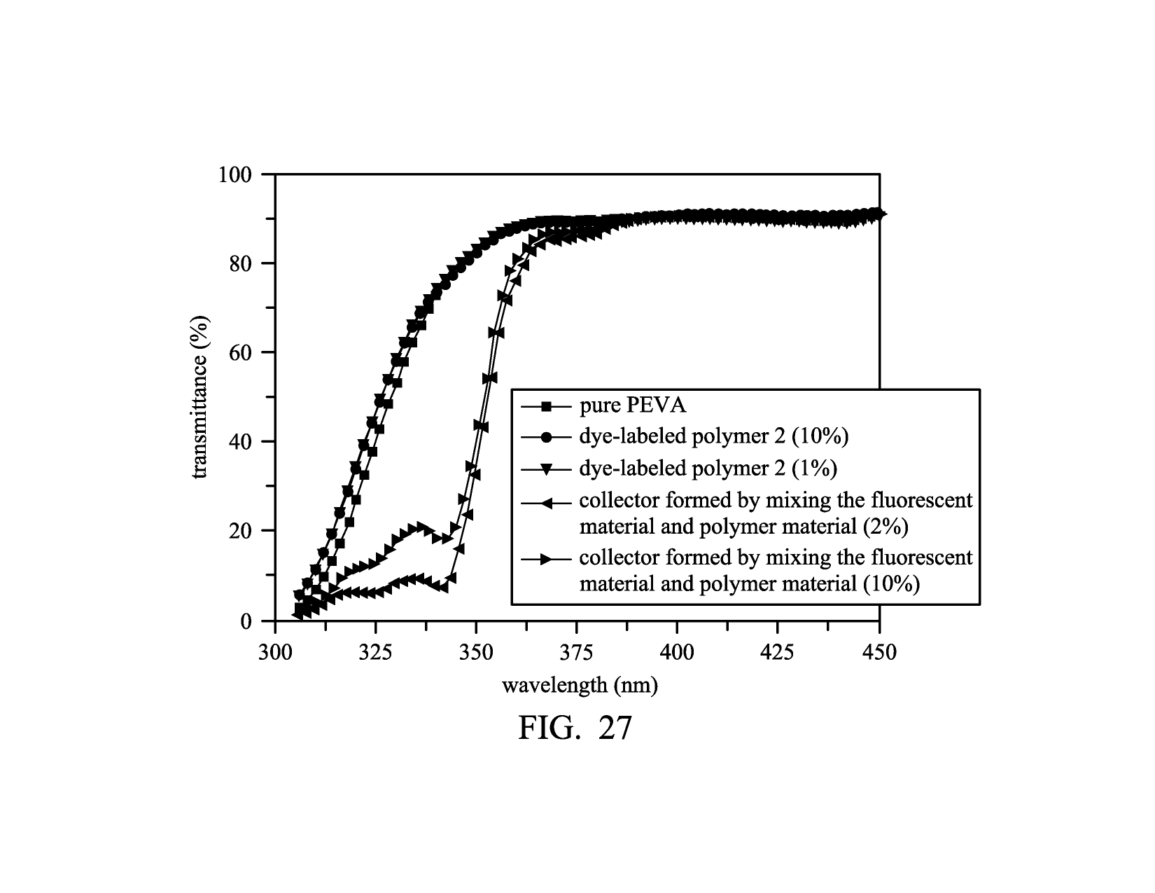

Referring to FIG. 27, the wavelength conversion material formed by mixing (comparative example) resulted in a decrease of the transmittance of the solar collector, and the possible reason was the poor compatibility between the fluorescent material and the polymer material. On the other hand, since the compatibility between the dye-labeled polymer of Example 1 and the polymer material had been improved, the solar collector had a good transmittance.

### Example 3

### Fluorescent Intensity of the Dye-Labeled Polymer

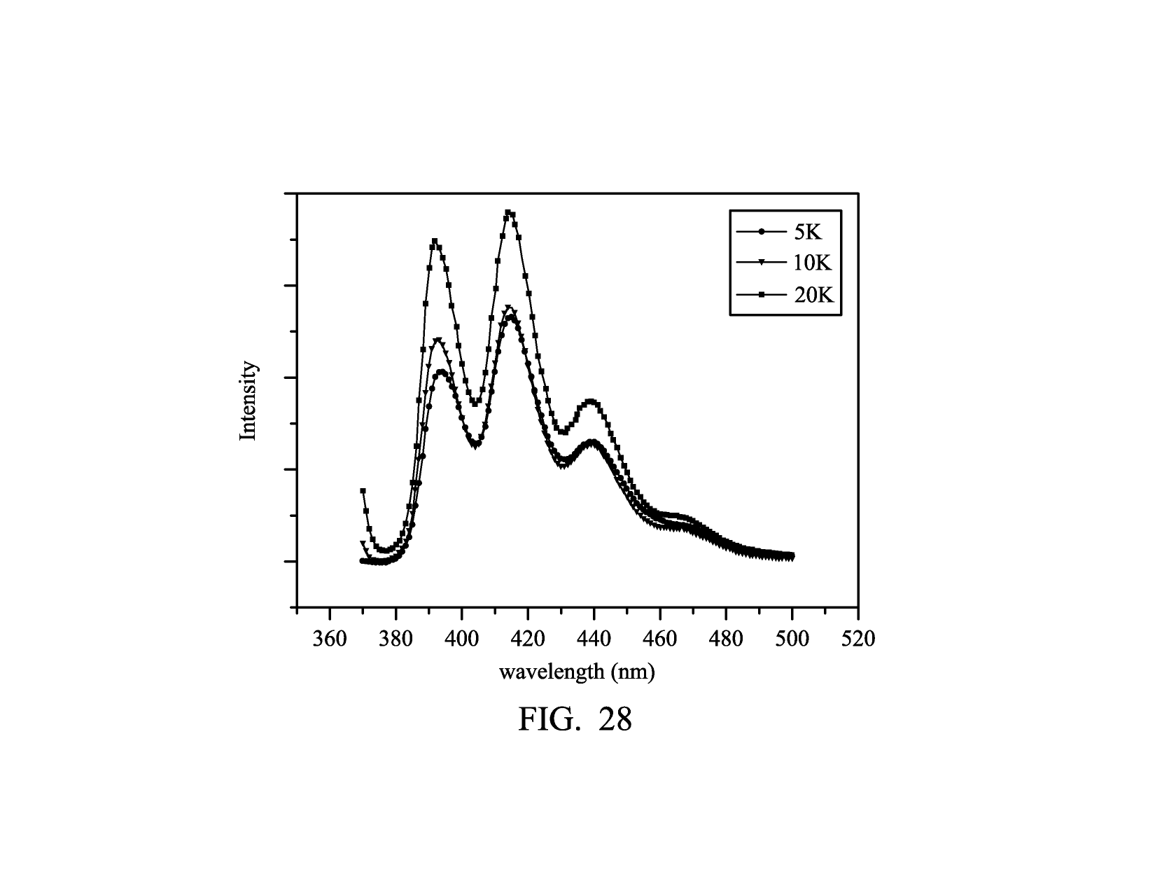

The m value of the dye-labeled polymer 2 in Example 1 was altered by the ratio between the polymer monomer and fluorescent monomer. The fluorescent intensities of the resulting dye-labeled polymers were analyzed and the result is shown in FIG. 28. In FIG. 28, 5 k, 10 K, and 20 K represent m value of 50, 100, and 200.

While the disclosure has been described by way of example and in terms of the preferred embodiments, it is to be understood that the disclosure is not limited to the disclosed embodiments. To the contrary, it is intended to cover various modifications and similar arrangements (as would be apparent to the skilled in the art). Therefore, the scope of the appended claims should be accorded the broadest interpretation so as to encompass all such modifications and similar arrangements.

1. A dye-labeled polymer, comprising a fluorescent dye moiety and a polymer moiety, wherein the fluorescent dye moiety and the polymer moiety are connected by a chemical bond.

2. The dye-labeled polymer as claimed in claim 1, wherein the polymer moiety comprises moieties of poly(ε-caprolactone), polyethylene, polyvinyl alcohol, polystyrene, or copolymers thereof.

3. The dye-labeled polymer as claimed in claim 1, wherein the fluorescent dye moiety comprises 1,2-coumarin moiety, perylene moiety, naphthalene moiety, pyrene moiety, polymethine moiety, carbazole moiety, anthracene moiety, or combinations thereof.

4. The dye-labeled polymer as claimed in claim 1, wherein a mole ratio of the polymer moiety to the fluorescent dye moiety is between 1:20 and 1:1000.

5. The dye-labeled polymer as claimed in claim 1, wherein absorption wavelength of the dye-labeled polymer is between 200 nm and 400 nm.

6. The dye-labeled polymer as claimed in claim 1, wherein photo luminescence wavelength of the dye-labeled polymer is between 350 nm and 1100 nm.

7. The dye-labeled polymer as claimed in claim 1, wherein solubility parameter of the dye-labeled polymer is between 8 MPa^{1/2} and 25 MPa^{1/2}.

8. A solar collector, comprising
a waveguide;
a wavelength conversion material disposed on the waveguide, wherein the wavelength conversion material comprises:
0-95 parts by weight of a polymer material; and
5-100 parts by weight of the dye-labeled polymer as claimed in claim 1, wherein the polymer material is different from the dye-labeled polymer.

9. The solar collector as claimed in claim 8, wherein the waveguide comprises a rigid substrate or a flexible substrate.

10. The solar collector as claimed in claim 8, wherein the polymer material comprises polyethylene vinyl acetate, polymethacrylate, polycarbonate resin, poly vinyl butral, epoxy resin, or combinations thereof.

11. The solar collector as claimed in claim 8, wherein a difference between a solubility parameter of the polymer material and a solubility parameter of the dye-labeled polymer is between ±15 MPa^{1/2}.

12. The solar collector as claimed in claim 8, wherein the solar collector is used in a solar cell or a solar photovoltaic glass.

13. A solar collector, comprising
a waveguide;
at least one fluorescent column embedded in the waveguide, wherein the fluorescent column comprises a wavelength conversion material, wherein the wavelength conversion material absorbs light having a first wavelength and emits light having a second wavelength, and the first wavelength is smaller than the second wavelength.

14. The solar collector as claimed in claim 13, wherein the fluorescent column comprises various fluorescent materials.

15. The solar collector as claimed in claim 13, wherein the fluorescent column comprises a cylinder, a hollow cylinder, a rectangular cylinder, a hollow rectangular cylinder, a polygon, or combinations thereof.

16. The solar collector as claimed in claim 13, wherein a width of the fluorescent column is between 10 μm and 100 μm.

17. The solar collector as claimed in claim 16, wherein the fluorescent column forms a specific shape in the waveguide, and the specific shape comprises a palisade shape, a web shape, or combinations thereof.

18. The solar collector as claimed in claim 13, wherein a width of the fluorescent column is larger than 100 μm.

19. The solar collector as claimed in claim 18, wherein the fluorescent column forms a specific shape in the waveguide, and the specific shape comprises a palisade shape, a web shape, a pattern, a letter, a symbol, or combinations thereof.

20. The solar collector as claimed in claim 13, wherein the first wavelength is between 300 nm and 1000 nm, and the second wavelength is between 700 nm and 1000 nm.

21. The solar collector as claimed in claim 13, wherein the wavelength conversion material comprises a dye-labeled polymer comprising a fluorescent dye moiety and a polymer moiety, wherein the fluorescent dye moiety and the polymer moiety are connected by a chemical bond.

22. The solar collector as claimed in claim 13, wherein the wavelength conversion material comprises:
0-95 parts by weight of a polymer material; and
5-100 parts by weight of a dye-labeled polymer comprising a fluorescent dye moiety and a polymer moiety, wherein the fluorescent dye moiety and the polymer moiety are connected by a chemical bond, wherein the polymer material is different from the dye-labeled polymer.

23. The solar collector as claimed in claim 13, further comprising a plurality of fluorescent columns, wherein the plurality of fluorescent columns is connected by a continuous film.

24. A method for manufacturing a solar collector, comprising
providing a first waveguide and a second waveguide;
forming at least one first cylinder trench at a surface of the first waveguide;
filling a first fluorescent material into the first cylinder trench to form a first fluorescent column; and
assembling the first waveguide and the second waveguide, wherein the first fluorescent column is embedded between the first waveguide and the second waveguide to form an embedded fluorescent column.

25. The method for manufacturing a solar collector as claimed in claim 24, before the step of assembling the first waveguide and the second waveguide, further comprising:
forming at least one second cylinder trench at a surface of the second waveguide; and
filling a second fluorescent material into the second cylinder trench to form a second fluorescent column.

26. The method for manufacturing a solar collector as claimed in claim 25, wherein after assembling the first waveguide and the second waveguide, the first fluorescent column and the second fluorescent column are attached to each other.

27. The method for manufacturing a solar collector as claimed in claim 24, wherein the first cylinder trench is formed by stamping, etching, laser printing, or combinations thereof.

28. A method for manufacturing a solar collector, comprising
providing a waveguide, wherein the waveguide has a main surface and a side surface;
forming at least one cylinder hole from the side surface of the waveguide, wherein the cylinder hole extends into the waveguide; and
filling a fluorescent material into the cylinder hole to embed a fluorescent column in the waveguide.

29. The method for manufacturing a solar collector as claimed in claim 28, wherein the cylinder hole is formed by laser drilling, ion beam drilling, or combinations thereof.

30. The method for manufacturing a solar collector as claimed in claim 28, wherein the cylinder hole passes through the waveguide.

31. The method for manufacturing a solar collector as claimed in claim 28, wherein the cylinder hole does not pass through the waveguide.

32. A method for manufacturing a solar collector, comprising
providing a first waveguide, wherein the first waveguide has at least one cylinder trench;
coating a fluorescent material on the first waveguide; and
attaching a second waveguide on the first waveguide having the fluorescent material, wherein the fluorescent material forms at least one fluorescent column in the cylinder trench.

33. The method for manufacturing a solar collector as claimed in claim 32, further comprising forming a plurality of fluorescent columns, wherein the plurality of fluorescent columns is connected by a continuous film.

34. A solar cell module, comprising
the solar collector as claimed in claim 8; and
a solar cell optically coupled to the solar collector, collecting and converting light, which passes through the solar collector, into energy.

35. An off-grid lamp, comprising
the solar collector as claimed in claim 8;
a solar cell optically coupled to the solar collector, collecting and converting light, which passes through the solar collector, into energy;
an electricity storage device electrically connected to the solar cell, receiving and storing the electricity output from the solar cell; and
a light emitting diode die electrically connected to the electricity storage device.

36. The off-grid lamp as claimed in claim 35, further comprising a switch electrically connected to the electricity storage device.

37. A solar cell module, comprising
the solar collector as claimed in claim 13;
a solar cell optically coupled to the solar collector, collecting and converting light, which passes through the solar collector, into energy.

38. An off-grid lamp, comprising
the solar collector as claimed in claim 13;
a solar cell optically coupled to the solar collector, collecting and converting light, which passes through the solar collector, into energy;
an electricity storage device electrically connected to the solar cell, receiving and storing the electricity output from the solar cell; and
a light emitting diode die electrically connected to the electricity storage device.
